(19) United States
(12) Patent Application Publication
(10) Pub. No.: US 2016/0179004 A1
(43) Pub. Date: Jun. 23, 2016

(54) PHOTOSENSITIVE POLYSILOXANE COMPOSITION, PROTECTING FILM, AND ELEMENT HAVING PROTECTIVE FILM

(71) Applicant: Chi Mei Corporation, Tainan City (TW)

(72) Inventors: I-kuang Chen, New Taipei City (TW); Ming-Ju Wu, Tainan City (TW); Chun-An Shih, Tainan City (TW)

(21) Appl. No.: 14/965,868

(22) Filed: Dec. 10, 2015

(30) Foreign Application Priority Data
Dec. 22, 2014 (TW) 103144749

(51) Int. Cl. G03F 7/075

(52) U.S. Cl. CPC G03F 7/0757

(57) ABSTRACT

A photosensitive polysiloxane composition having good developing properties and good operational reliability of development, a protective film, and an element having the protective film are provided. The photosensitive polysiloxane composition includes an alkali-soluble resin (A), a compound (B) having an ethylenically unsaturated group, a photoinitiator (C), and a solvent (D). The alkali-soluble resin (A) includes a polysiloxane (A-1). The compound (B) having an ethylenically unsaturated group includes a compound (B-1) having an ethylenically unsaturated group, wherein the compound (B-1) having an ethylenically unsaturated group includes at least one of a (meth)acrylate monomer represented by formula (1) and a (meth)acrylate monomer represented by formula (2).

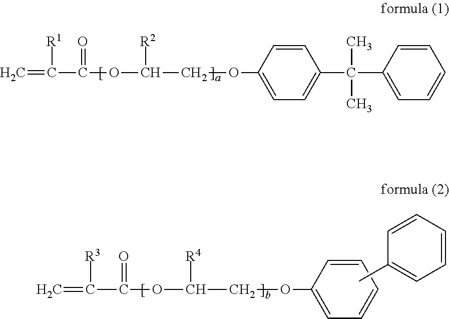

### CROSS-REFERENCE TO RELATED APPLICATION

This application claims the priority benefit of Taiwan application serial no. 103144749, filed on Dec. 22, 2014. The entirety of the above-mentioned patent application is hereby incorporated by reference herein and made a part of this specification.

### BACKGROUND OF THE INVENTION

1. Field of the Invention

The invention relates to a photosensitive polysiloxane composition, a protective film, and an element having the protective film. More particularly, the invention relates to a photosensitive polysiloxane composition having good developing properties and good operational reliability of development, a protective film formed thereby, and an element having the protective film.

2. Description of Related Art

In a display element such as a liquid crystal display element, an integrated circuit element, a solid state imaging device, or organic electroluminescence, a cured film such as a protective film used to prevent degradation or damage to an electronic component represented by a touch panel or an interlayer insulating film used to maintain insulation between wirings disposed in layers is provided. To form such cured film, a radiation-sensitive composition has always been used. For instance, a coating film of a radiation-sensitive composition can be formed on a substrate, and radiation is irradiated (hereinafter “exposure”) via a photo mask having a predetermined pattern, and then the undesired portion is dissolved and removed by performing development using an organic alkali developing solution, thus forming a cured film.

For the cured film used as the protective film of a touch panel, characteristics such as high adhesion of the wirings of a touch panel element, smooth film and high hardness of film, excellent scratch-resistance, no color change and no loss of transparency under a high temperature condition (thermal-resisted transmittance), no generation of cracking (cracks) under a high temperature condition (thermal-resisted cracking), excellent sensitivity to radiation, and forming of good pattern without residual film of development (developability) are desired.

Moreover, in the cured film used as an interlayer insulating film, the pattern of a contact hole for wiring needs to be formed. Therefore, in addition to the desired characteristics of a protective film, it is further desired to form a pattern (high resolution) via high resolution and high fineness.

Conventionally, the component of a radiation-sensitive composition is mainly an acrylic-based resin. However, in recent years, a polysiloxane-based material has gained attention due to superior heat resistance and transparency compared to the acrylic-based resin (patent literature 1 to patent literature 3). However, the adhesion of a polysiloxane-based material and an indium tin oxide (ITO) substrate is insufficient, and cracking is readily generated. Therefore, a polysiloxane-based material has the issue of impracticality as a protective film. Moreover, the development of a negative-type radiation-sensitive composition as the material for the foaming of the interlayer insulating film of a liquid crystal display element is in progress (patent literature 4). However, such negative-type radiation-sensitive composition does not readily form a contact hole having an aperture at a practically usable level. Therefore, in terms of forming a superior contact hole, to form the interlayer insulating film of a display element, a positive-type radiation-sensitive composition is widely used (patent literature 5).

Moreover, the following radiation-sensitive composition has been proposed, which is formed by containing a siloxane oligomer having an oxiranyl group, an oxetanyl group, or a mercapto group in the form of an additive in a very small amount in a composition containing a copolymer of unsaturated carboxylic acid and/or unsaturated carboxylic anhydride and other unsaturated compounds, a polymerizable unsaturated compound, and a photopolymerization initiator. Moreover, the radiation-sensitive composition can be suitably applied in the for thing of a spacer in a display element (patent literature 6). However, the application of the spacer of a display element is different from that of a protective film or an interlayer insulating film, and therefore it is difficult to sufficiently obtain all of the desired characteristics of a protective film or an interlayer insulating film.

### PRIOR TECHNICAL LITERATURES

### Patent Literatures

[Patent literature 1] Japanese Patent Laid-Open Publication No. 2000-001648

[Patent literature 2] Japanese Patent Laid-Open Publication No. 2006-178436

[Patent literature 3] Japanese Patent Laid-Open Publication No. 2008-248239

[Patent literature 4] Japanese Patent Laid-Open Publication No. 2000-162769

[Patent literature 5] Japanese Patent Laid-Open Publication No. 2001-354822

[Patent literature 6] Japanese Patent Laid-Open Publication No. 2008-233518

However, the developing properties of the radiation-sensitive compositions of patent literature 1 to patent literature 6 are poor and do not meet industrial standards. Moreover, when development is performed on the radiation-sensitive compositions of patent literature 1 to patent literature 6 to form a protective film, the operational reliability of development is poor, and therefore process conditions are not readily managed.

Therefore, how to reach the demands of current industries for developing properties and operational reliability of development is an object of active research of those skilled in the art.

### SUMMARY OF THE INVENTION

Accordingly, the invention provides a photosensitive polysiloxane composition having good developing properties and good operational reliability of development, a protective film, and an element having the protective film.

The invention provides a photosensitive polysiloxane composition including an alkali-soluble resin (A), a compound (B) having an ethylenically unsaturated group, a photoinitiator (C), and a solvent (D). The alkali-soluble resin (A) includes a polysiloxane (A-1). The compound (B) having an ethylenically unsaturated group includes a compound (B-1) having an ethylenically unsaturated group, wherein the compound (B-1) having an ethylenically unsaturated group includes at least one of a (meth)acrylate monomer represented by formula (1) and a (meth)acrylate monomer represented by formula (2).

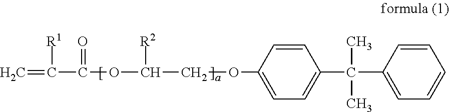

In formula (1), R¹ and R² each independently represent a hydrogen atom or a methyl group; a represents a number of 0 to 4.

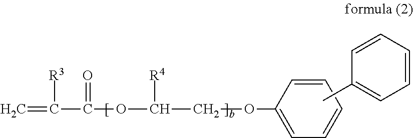

In formula (2), R³ and R⁴ each independently represent a hydrogen atom or a methyl group; b represents a number of 0 to 4.

In an embodiment of the invention, the polysiloxane (A-1) is obtained from the polycondensation of a silane monomer component, and the silane monomer component includes a compound represented by formula (I-1) and a compound represented by formula (I-2).

Si(R^{a})_{w}(OR^{b})_{4-w} formula (I-1)

In formula (I-1), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group, at least one R^{a} is an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3.

Si(R^{c})ᵤ(OR^{d})₄₋ᵤ formula (I-2)

In formula (I-2), R^{c} each independently represents a hydrogen atom, a C₁ to C₁₀ alkyl group, a C₂ to C₁₀ alkenyl group, or a C₆ to C₁₅ aryl group; R^{d} each independently represents a hydrogen atom, a C₁ to C₆ alkyl group, a C₁ to C₆ acyl group, or a C₆ to C₁₅ aryl group; and u represents an integer of 0 to 3.

In an embodiment of the invention, based on 100 parts by weight of the alkali-soluble resin (A), the usage amount of the polysiloxane (A-1) is 30 parts by weight to 100 parts by weight, the usage amount of the compound (B) having an ethylenically unsaturated group is 5 parts by weight to 100 parts by weight, the usage amount of the compound (B-1) having an ethylenically unsaturated group is 0.5 parts by weight to 10 parts by weight, the usage amount of the photoinitiator (C) is 3 parts by weight to 30 parts by weight, and the usage amount of the solvent (D) is 50 parts by weight to 500 parts by weight.

In an embodiment of the invention, the compound (B) having an ethylenically unsaturated group further includes a urethane(meth)acrylate compound (B-2) having at least six (meth)acryloyl groups.

In an embodiment of the invention, based on 100 parts by weight of the alkali-soluble resin (A), the usage amount of the urethane(meth)acrylate compound (B-2) having at least six (meth)acryloyl groups is 1 part by weight to 30 parts by weight.

In an embodiment of the invention, the alkali-soluble resin (A) further includes an alkali-soluble resin (A-2), wherein the alkali-soluble resin (A-2) is obtained by copolymerizing an unsaturated carboxylic acid or unsaturated carboxylic anhydride compound (a-2-1), an unsaturated compound (a-2-2) containing an epoxy group, and other unsaturated compounds (a-2-3).

In an embodiment of the invention, the unsaturated compound (a-2-2) containing an epoxy group includes an unsaturated compound (a-2-2a) containing an oxetanyl group.

The invention further provides a protective film formed by coating the above photosensitive polysiloxane composition on an element, and then performing pre-bake, exposure, development, and post-bake.

The invention further provides an element having a protective film, including an element and the above protective film, wherein the protective film covers the element.

Based on the above, since the photosensitive polysiloxane composition of the invention contains polysiloxane and a compound having an ethylenically unsaturated group (such as (meth)acryloyl group), the developing properties are good and the operational reliability of development is good. Therefore, the photosensitive polysiloxane composition of the invention is suitable for the forming of a protective film.

To make the above features and advantages of the invention more comprehensible, several embodiments are described in detail as follows.

### DESCRIPTION OF THE EMBODIMENTS

<Photosensitive polysiloxane Composition>

The invention provides a photosensitive polysiloxane composition including an alkali-soluble resin (A), a compound (B) having an ethylenically unsaturated group, a photoinitiator (C), and a solvent (D). Moreover, the photosensitive polysiloxane composition can further include an additive (E) if needed.

In the following, the individual components used in the photosensitive polysiloxane composition of the invention are described in detail.

It should be mentioned that, in the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### Alkali-soluble Resin (A)

The alkali-soluble resin (A) includes a polysiloxane (A-1) and an alkali-soluble resin (A-2).

### Polysiloxane (A-1)

The type of the polysiloxane polymer (A) is not particularly limited, and any type thereof capable of achieving the object of the invention can be used. The polysiloxane (A-1) is obtained via polycondensation (i.e., hydrolysis and partial condensation) of a silane monomer component, wherein the silane monomer component includes a silane monomer (a-1). Moreover, the silane monomer component can further include a silane monomer (a-2) other than the silane monomer (a-1), a siloxane prepolymer (a-3), a silica particle (a-4), or a combination thereof, but is not limited thereto. Each component of the silane monomer component and the reaction steps and the conditions of the polycondensation are further described below.

Silane monomer (a-1)

The silane monomer (a-1) is a compound represented by formula (I-1).

Si(R^{a})_{w}(OR^{b})_{4-w} formula (I-1)

In formula (I-1), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group, at least one R^{a} is an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3.

More specifically, when R^{a} in formula (I-1) represents a C₁ to C₁₀ alkyl group, specifically, R^{a} is, for instance, a methyl group, an ethyl group, an n-propyl group, an isopropyl group, an n-butyl group, a tert-butyl group, an n-hexyl group, or an n-decyl group. Moreover, R^{a} can also be an alkyl group having other substituents. Specifically, R^{a} is, for instance, trifluoromethyl, 3,3,3-trifluoropropyl, 3-aminopropyl, 3-mercaptopropyl, or 3-isocyanatepropyl.

When R^{a} in formula (I-1) represents a C₂ to C₁₀ alkenyl group, specifically, R^{a} is, for instance, a vinyl group. Moreover, R^{a} can also be an alkenyl group having other substituents. Specifically, R^{a} is, for instance, 3-acryoyloxypropyl or 3-methylacryloyloxypropyl.

When R^{a} in formula (I-1) represents a C₆ to C₁₅ aryl group, specifically, R^{a} is, for instance, a phenyl group, a tolyl group, or a naphthyl group. Moreover, R^{a} can also be an aryl group having other substituents. Specifically, R^{a} is, for instance, o-hydroxyphenyl, 1-(o-hydroxyphenyl)ethyl, 2-(o-hydroxyphenyl)ethyl, or 4-hydroxy-5-(p-hydroxyphenylcarbonyloxy)pentyl.

Moreover, R^{a} in formula (I-1) represents an alkyl group containing an anhydride group, wherein the alkyl group is preferably a C₁ to C₁₀ alkyl group. Specifically, the alkyl group containing an anhydride group is, for instance, ethyl succinic anhydride shown in formula (I-1-1), propyl succinic anhydride shown in formula (I-1-2), or propyl glutaric anhydride shown in formula (I-1-3). It should be mentioned that, the anhydride group is a group formed by intramolecular dehydration of a dicarboxylic acid, wherein the dicarboxylic acid is, for instance, succinic acid or glutaric acid.

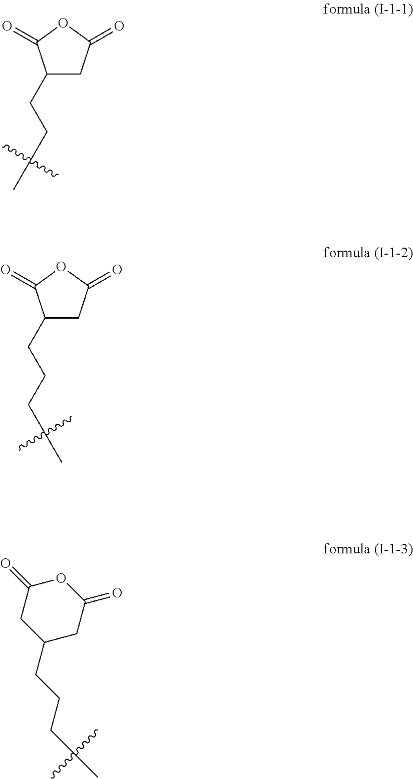 [SMILES: *CCC1CC(=O)OC1=O ; *CCCC1CC(=O)OC1=O ; *CCCC1CC(=O)OC(=O)C1]

Moreover, R^{a} in formula (I-1) represents an alkyl group containing an epoxy group, wherein the alkyl group is preferably a C₁ to C₁₀ alkyl group. Specifically, the alkyl group containing an epoxy group is, for instance, oxetanylpentyl or 2-(3,4-epoxycyclohexyl)ethyl. It should be mentioned that, the epoxy group is a group formed by intramolecular dehydration of diol, wherein the diol is, for instance, propanediol, butanediol, or pentanediol.

R^{a} in formula (I-1) represents an alkoxy group containing an epoxy group, wherein the alkoxy group is preferably a C₁ to C₁₀ alkoxy group. Specifically, the alkoxy group containing an epoxy group is, for instance, glycidoxypropyl or 2-oxetanylbutoxy.

Moreover, when R^{b} in formula (I-1) represents a C₁ to C₆ alkyl group, specifically, R^{b} is, for instance, a methyl group, an ethyl group, an n-propyl group, an isopropyl group, or an n-butyl group. When R^{b} in formula (I-1) represents a C₁ to C₆ acyl group, specifically, R^{b} is, for instance, an acetyl group. When R^{b} in formula (I-1) represents a C₆ to C₁₅ aryl group, specifically, R^{b} is, for instance, a phenyl group.

In formula (I-1), w represents an integer of 1 to 3. When w represents 2 or 3, a plurality of R^{a} can be the same or different, and when w represents 1 or 2, a plurality of R^{b} can be the same or different.

Specific examples of the silane monomer (a-1) include 3-glycidoxypropyltrimethoxysilane (TMS-GAA), 3-glycidoxypropyltriethoxysilane, 2-(3,4-epoxycyclohexyl) ethyl trimethoxy silane (ECETES), 2-oxetanylbutoxypropyl triphenoxysilane, a commercial product made by Toagosei: 2-oxetanylbutoxypropyltrimethoxysilane (product name: TMSOX-D), 2-oxetanylbutoxypropyltriethoxysilane (product name: TESOX-D), 3-(triphenoxysilyl)propyl succinic anhydride, a commercial product made by Shin-Etsu Chemical: 3-(trimethoxysilyl)propyl succinic anhydride (product name: X-12-967), a commercial product made by WACKER: 3-(triethoxysilyl)propyl succinic anhydride (product name: GF-20), 3-(trimethoxysilyl)propyl glutaric anhydride (TMSG), 3-(triethoxysilyl)propyl glutaric anhydride, 3-(triphenoxysilyl)propyl glutaric anhydride, diisopropoxy-di(2-oxetanylbutoxy propyl)silane (DIDOS), di(3-oxetanylpentyl)dimethoxy silane, (di-n-butoxysilyl) di(propyl succinic anhydride), (dimethoxysilyl) di(ethyl succinic anhydride), 3-glycidoxypropyldimethylmethoxysilane, 3-glycidoxypropyl dimethylethoxysilane, di(2-oxetanylbutoxypentyl)-2-oxetanyl pentylethoxy silane, tri(2-oxetanylpentyl)methoxy silane, (phenoxysilyl) tri(propyl succinic anhydride), (methyl methoxysilyl) di(ethyl succinic anhydride), or a combination of the compounds.

The silane monomer (a-1) can be used alone or in multiple combinations.

Specific examples of the silane monomer (a-1) preferably include 3-(triethoxysilyl)propyl succinic anhydride, 3-(trimethoxysilyl)propyl glutaric anhydride, (dimethoxysilyl) di(ethyl succinic anhydride), 2-oxetanylbutoxypropyltrimethoxysilane, 2-(3,4-epoxycyclohexyl)ethyltrimethoxysilane, 2-oxetanylbutoxypropyltriethoxysilane, or a combination of the compounds.

Based on a total amount of 100 mol % of the monomers in the silane monomer component, the usage amount of the silane monomer (a-1) is 0.5 mol % to 20 mol %, preferably 1 mol % to 15 mol %, and more preferably 1 mol % to 10 mol %. In the photosensitive polysiloxane composition, when the silane monomer component forming the polysiloxane (A-1) contains the silane monomer (a-1), the developing properties of the photosensitive polysiloxane composition are better.

Silane monomer (a-2)

The silane monomer (a-2) is a compound represented by formula (I-2).

Si(R^{c})ᵤ(OR^{d})₄₋ᵤ formula (I-2)

In formula (I-2), R^{c} each independently represents a hydrogen atom, a C₁ to C₁₀ alkyl group, a C₂ to C₁₀ alkenyl group, or a C₆ to C₁₅ aryl group; R^{d} each independently represents a hydrogen atom, a C₁ to C₆ alkyl group, a C₁ to C₆ acyl group, or a C₆ to C₁₅ aryl group; and u represents an integer of 0 to 3.

More specifically, when R^{e} in formula (I-2) represents a C₁ to C₁₀ alkyl group, specifically, R^{e} is, for instance, a methyl group, an ethyl group, an n-propyl group, an isopropyl group, an n-butyl group, a tert-butyl group, an n-hexyl group, or an n-decyl group. Moreover, R^{c} can also be an alkyl group having other substituents. Specifically, R^{e} is, for instance, trifluoromethyl, 3,3,3-trifluoropropyl, 3-aminopropyl, 3-mercaptopropyl, or 3-isocyanatepropyl.

When R^{c} in formula (I-2) represents a C₂ to C₁₀ alkenyl group, specifically, R^{c} is, for instance, a vinyl group. Moreover, R^{e} can also be an alkenyl group having other substituents. Specifically, R^{c} is, for instance, 3-acryoyloxypropyl or 3-methylacryloyloxypropyl.

When R^{e} in formula (I-2) represents a C₆ to C₁₅ aryl group, specifically, R^{e} is, for instance, a phenyl group, a tolyl group, or a naphthyl group. Moreover, R^{c} can also be an aryl group having other substituents. Specifically, R^{c} is, for instance, o-hydroxyphenyl, 1-(o-hydroxyphenyl)ethyl, 2-(o-hydroxyphenyl)ethyl, or 4-hydroxy-5-(p-hydroxyphenylcarbonyloxy)pentyl.

Moreover, when R^{d} in formula (I-2) represents a C₁ to C₆ alkyl group, specifically, R^{d} is, for instance, a methyl group, an ethyl group, an n-propyl group, an isopropyl group, or an n-butyl group. When R^{d} in formula (I-2) represents a C₁ to C₆ acyl group, specifically, R^{d} is, for instance, an acetyl group. When R^{d} in formula (I-2) represents a C₆ to C₁₅ aryl group, specifically, R^{d} is, for instance, a phenyl group.

In formula (I-2), u is an integer of 0 to 3. When u represents 2 or 3, a plurality of R^{e} can be the same or different; when u represents 0, 1, or 2, a plurality of R^{d} can be the same or different.

In formula (I-2), when u=0, the silane monomer is a tetrafunctional silane monomer (i.e., a silane monomer having four hydrolyzable groups); when u=1, the silane monomer is a trifunctional silane monomer (i.e., a silane monomer having three hydrolyzable groups); when u=2, the silane monomer is a bifunctional silane monomer (i.e., a silane monomer having two hydrolyzable groups); and when u=3, the silane monomer is a monofunctional silane monomer (i.e., a silane monomer having one hydrolyzable group). It should be mentioned that, the hydrolyzable group refers to a group capable of being reacted in a hydrolysis reaction and bonded to silicon. For instance, the hydrolyzable group is, for instance, an alkoxy group, an acyloxy group, or a phenoxy group.

Specific examples of the silane monomer represented by formula (I-2) include, but are not limited to:

(1) a tetrafunctional silane monomer: tetramethoxysilane, tetraethoxysilane, tetraacetoxysilane, or tetraphenoxy silane;

(2) a trifunctional silane monomer: methyltrimethoxysilane (MTMS), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, phenyltrimethoxysilane (PTMS), phenyltriethoxysilane (PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-mercaptopropyltrimethoxysilane, 3-acryloyloxypropyltrimethoxysilane, 3-methacryloyloxypropyltrimethoxysilane, or 3-methylacryloyloxypropyltriethoxysilane;

(3) a bifunctional silane monomer: dimethyldimethoxysilane (DMDMS), dimethyldiethoxysilane, dimethyldiacetyloxysilane, di-n-butyldimethoxysilane, or diphenyldimethoxysilane; or

(4) a monofunctional silane monomer: trimethylmethoxysilane or tri-n-butylethoxysilane . . . etc. The various silane monomers can be used alone or in multiple combinations.

Siloxane prepolymer (a-3)

The siloxane prepolymer (a-3) is a compound represented by formula (I-3).

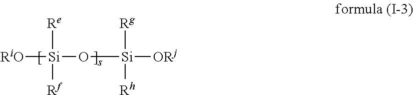

In formula (I-3), R^{e}, R^{f}, Rg, and R^{h} each independently represent a hydrogen atom, a C₁ to C₁₀ alkyl group, a C₂ to C₆ alkenyl group, or a C₆ to C₁₅ aryl group, wherein any one of the alkyl group, the alkenyl group, and the aryl group can optionally contain a substituent; Rand R^{j} each independently represent a hydrogen atom, a C₁ to C₆ alkyl group, a C₁ to C₁₀ acyl group, or a C₆ to C₁₅ aryl group, wherein any one of the alkyl group, the acyl group, and the aryl group can optionally contain a substituent; s represents an integer of 1 to 1000.

In formula (I-3), R^{e}, R^{f}, Rg, and R^{h} each independently represent a C₁ to C₁₀ alkyl group. For instance, R^{e}, R^{f}, R^{g}, and R^{h} are each independently a methyl group, an ethyl group, or an n-propyl group . . . etc. In formula (I-3), R^{e}, R^{f}, R^{g}, and R^{h} each independently represent a C₂ to _{C10} alkenyl group. For instance, R^{e}, R^{f}, Rg, and R^{h} are each independently a vinyl group, an acryloyloxypropyl group, or a methacryloyloxypropyl group. In formula (I-3), R^{e}, R^{f}, R^{g}, and R^{h} each independently represent a C₆ to C₁₅ aryl group. For instance, R^{e}, R^{f}, Rg, and R^{h} are each independently a phenyl group, a tolyl group, or a naphthyl group . . . etc. It should be mentioned that, any one of the alkyl group, the alkenyl group, and the aryl group can optionally have a substituent.

In formula (I-3), Rⁱ and R^{j} each independently represent a C₁ to C₆ alkyl group. For instance, Rⁱ and R^{j} are each independently a methyl group, an ethyl group, an n-propyl group, an isopropyl group, or an n-butyl group. In formula (I-3), Rⁱ and R^{j} each independently represent a C₁ to C₆ acyl group such as an acetyl group. In formula (I-3), Rⁱ and R^{j} each independently represent a C₆ to C₁₅ aryl group such as a phenyl group. It should be mentioned that, any one of the alkyl group, the acyl group, and the aryl group can optionally have a substituent.

In formula (I-3), s can be an integer of 1 to 1000, preferably an integer of 3 to 300, and more preferably an integer of 5 to 200. When s is an integer of 2 to 1000, R^{e} is each the same or a different group, and R^{f} is each the same or a different group.

Specific examples of the siloxane prepolymer (a-3) include, but are not limited to, ,1,3,3-tetramethyl-1,3-dimethoxydisiloxane, 1,1,3,3-tetramethyl-1,3-diethoxydisiloxane,1,3,3-tetraethyl-1,3-diethoxydisiloxane, or a commercial product (such as DMS-S12 (molecular weight: 400 to 700), DMS-S15 (molecular weight: 1500 to 2000), DMS-S21 (molecular weight: 4200), DMS-S27 (molecular weight: 18000), DMS-S31 (molecular weight: 26000), DMS-S32 (molecular weight: 36000), DMS-S33 (molecular weight: 43500), DMS-S35 (molecular weight: 49000), DMS-S38 (molecular weight: 58000), DMS-542 (molecular weight: 77000), or PDS-9931 (molecular weight: 1000 to 1400)) of silanol-terminated polydimethylsiloxane made by Gelest Inc.

The siloxane prepolymer (a-3) can be used alone or in multiple combinations.

Silica Particle (a-4)

The average particle size of the silica particle (a-4) is not particularly limited. The average particle size ranges from 2 nm to 250 nm, preferably 5 nm to 200 nm, and more preferably 10 nm to 100 nm.

Specific examples of the silica particle include, but are not limited to, a commercial product made by JGC Catalysts & Chemicals Co., Ltd. (such as OSCAR 1132 (particle size: 12 nm; dispersant: methanol), OSCAR 1332 (particle size: 12 nm; dispersant: n-propanol), OSCAR 105 (particle size: 60 nm; dispersant: y-butyrolactone), or OSCAR 106 (particle size: 120 nm; dispersant: diacetone alcohol)); a commercial product made by Fuso Chemical Co. (such as Quartron PL-1-IPA (particle size: 13 nm; dispersant: isopropyl alcohol), Quartron PL-1-TOL (particle size: 13 nm; dispersant: toluene), Quartron PL-2L-PGME (particle size: 18 nm; dispersant: propylene glycol monomethyl ether), or Quartron PL-2L-MEK (particle size: 18 nm; dispersant: methyl ethyl ketone)); or a commercial product made by Nissan Chemical Industries (such as IPA-ST (particle size: 12 nm; dispersant: isopropyl alcohol), EG-ST (particle size: 12 nm; dispersant: ethylene glycol), IPA-ST-L (particle size: 45 nm; dispersant: isopropyl alcohol), or IPA-ST-ZL (particle size: 100 nm; dispersant: isopropyl alcohol)). The silica particle can be used alone or in multiple combinations.

Reaction Steps and Conditions of polycondensation

In general, the polycondensation reaction is performed via the following steps: a solvent or water is added in a silane monomer component, or a catalyst can be optionally added; and the mixture is heated and stirred under 50° C. to 150° C. for 0.5 hours to 120 hours, and a by-product (such as alcohol or water) can be further removed via distillation.

The solvent used in the polycondensation reaction is not particularly limited, and the solvent can be the same or different from the solvent (D) included in the photosensitive polysiloxane composition of the invention. Based on a total amount of 100 g of the silane monomer component, the usage amount of the solvent is preferably 15 g to 1200 g, more preferably 20 g to 1100 g; and still more preferably 30 g to 1000 g.

Based on 1 mole of the hydrolyzable group of the silane monomer component, the water used in the polycondensation reaction (i.e., water used for hydrolysis) is 0.5 moles to 2 moles.

The catalyst used in the polycondensation reaction is not particularly limited, and is preferably selected from an acidic catalyst or a basic catalyst. Specific examples of the acidic catalyst include, but are not limited to, for instance, hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or an ion exchange resin. Specific examples of the basic catalyst include, but are not limited to, for instance, diethylamine, triethylamine, tripropylamine, tributylamine, tripentylamine, trihexylamine, triheptylamine, trioctylamine, diethanolamine, triethanolamine, sodium hydroxide, potassium hydroxide, silane containing an amine group and having an alkoxy group, or an ion exchange resin.

Based on a total amount of 100 g of the silane monomer component, the usage amount of the catalyst is preferably 0.005 g to 15 g, more preferably 0.01 g to 12 g; and still more preferably 0.05 g to 10 g.

From the point of view of stability, the polysiloxane (A-1) preferably does not contain a by-product (such as alcohol or water) and a catalyst. Therefore, purification can optionally be performed on the reaction mixture after the polycondensation reaction to obtain the polysiloxane (A-1). The method of purification is not particularly limited, and is preferably capable of diluting the reaction mixture via a hydrophobic solvent. Then, the hydrophobic solvent and the reaction mixture are transferred to a separation funnel. Next, the organic layer is washed with water several times, and the organic layer is concentrated via a rotary evaporator to remove the alcohol or water. Moreover, an ion exchange resin can be used to remove the catalyst.

Based on 100 parts by weight of the alkali-soluble resin (A), the usage amount of the polysiloxane (A-1) can be 30 to 100 parts by weight, preferably 50 to 100 parts by weight, and more preferably 50 to 99 parts by weight.

When the photosensitive polysiloxane composition does not contain the polysiloxane (A-1), the operational reliability of development is poor.

### Alkai-Soluble Resin (A-2)

The alkali-soluble resin (A-2) can be a copolymer containing a structural unit having a carboxyl group and a structural unit having an epoxy group and other structural units, wherein the structural unit having a carboxyl group is from an unsaturated carboxylic acid or unsaturated carboxylic anhydride compound (a-2-1), and the structural unit having an epoxy group is preferably from an unsaturated compound (a-2-2) containing an epoxy group. Specifically, the alkali-soluble resin (A-2) is obtained by copolymerizing an unsaturated carboxylic acid or unsaturated carboxylic anhydride compound (a-2-1), an unsaturated compound (a-2-2) containing an epoxy group, and other unsaturated compounds (a-2-3).

Unsaturated Carboxylic Acid or Unsaturated Carboxylic anhydride Compound (a-2-1)

Specific examples of the unsaturated carboxylic acid or unsaturated carboxylic anhydride compound (a-2-1) include, for instance, a monocarboxylic acid such as acrylic acid, methacrylic acid, crotonic acid, 2-acryloyloxy ethyl succinic acid, 2-methacryloyloxy ethyl succinic acid, 2-acryloyloxy ethyl hexahydrophthalate, or 2-methacryloyloxy ethyl hexahydrophthalate; a dicarboxylic acid such as maleic acid (i.e., cis-butenedioic acid), fumaric acid (i.e., trans-butenedioic acid), or citraconic acid (i.e., cis-methylbutenedioic acid); an anhydride of the dicarboxylic acids; or a combination of the dicarboxylic acids and an anhydride thereof. Among the unsaturated carboxylic acids or unsaturated carboxylic anhydride compounds (a-2-1), in terms of copolymerization reactivity and solubility of the obtained copolymer in the alkali developing solution, acrylic acid, methacrylic acid, 2-acryloyloxy ethyl succinic acid, 2-methacryloyloxy ethyl succinic acid, or maleic anhydride is preferred.

The unsaturated carboxylic acid or unsaturated carboxylic anhydride compound (a-2-1) can be used alone or in multiple combinations.

Based on a total usage amount of 100 parts by weight of the unsaturated carboxylic acid or unsaturated carboxylic anhydride compound (a-2-1), the compound (a-2-2) containing an epoxy group, and the other unsaturated compounds (a-2-3), the usage amount of the unsaturated carboxylic acid or unsaturated carboxylic anhydride compound (a-2-1) is 15 parts by weight to 40 parts by weight, preferably 18 parts by weight to 38 parts by weight, and more preferably 20 parts by weight to 35 parts by weight.

Unsaturated Compound (a-2-2) Containing epoxy Group

The unsaturated compound (a-2-2) containing an epoxy group includes at least one of a polymerizable unsaturated compound (a-2-2a) containing an oxetanyl group and other unsaturated compounds (a-2-2b) containing an epoxy group.

Specific examples of the polymerizable unsaturated compound (a-2-2a) containing an oxetanyl group include (meth)acrylate having an oxetanyl group such as 3-(methacryloyloxy methyl)oxetane, 3-(methacryloyloxy methyl)-3-ethyloxetane, 3-(methacryloyloxy methyl)-2-methyloxetane, 3-(methacryloyloxy ethyl)oxetane, 3-(methacryloyloxy ethyl)-3-ethyloxetane, 2-ethyl-3-(methacryloyloxy ethyl)oxetane, 3-(acryloyloxy methyl)oxetane, 3-(acryloyloxy methyl)-3-ethyloxetane, 3-(acryloyloxy methyl)-2-methyloxetane, 3-(acryloyloxy ethyl)oxetane, 3-(acryloyloxy ethyl)-3-ethyloxetane, 2-ethyl-3-(acryloyloxy ethyl)oxetane, 2-(methacryloyloxy methyl)oxetane, 2-methyl-2-(methacryloyloxy methyl)oxetane, 3-methyl-2-(methacryloyloxy methyl)oxetane, 4-methyl-2-(methacryloyloxy methyl)oxetane, 2-(2-(2-methyl oxetanyl)ethyl methacrylate, 2-(2-(3-methyl oxetanyl)ethyl methacrylate, 2-(methacryloyloxy ethyl)-2-methyloxetane, 2-(methacryloyloxy ethyl)-4-methyloxetane, 2-(acryloyloxy methyl)oxetane, 2-methyl-2-(acryloyloxy methyl)oxetane, 3-methyl-2-(acryloyloxy methyl)oxetane, 4-methyl-2-(acryloyloxy methyl)oxetane, 2-(acryloyloxy ethyl)-2-methyloxetane, or 2-(acryloyloxy ethyl)-4-methyloxetane, or a combination of the compounds.

When the alkali-soluble resin (A-2) is copolymerized by using the polymerizable unsaturated compound (a-2-2a) containing an oxetanyl group, the operational reliability of development is better.

Specific examples of the other unsaturated compounds (a-2-2b) containing an epoxy group include epoxyalkyl acrylate such as glycidyl acrylate, 2-methylglycidyl acrylate, 3,4-epoxybutyl acrylate, 6,7-epoxyheptyl acrylate, 3,4-epoxycyclohexyl acrylate, or 3,4-epoxycyclohexyl methacrylate; epoxyalkyl methacrylate such as glycidyl methacrylate, 2-methyl-glycidyl methacrylate, 3,4-epoxybutyl methacrylate, 6,7-epoxyheptyl methacrylate, 3,4-epoxycyclohexyl methacrylate, or 3,4-epoxycyclohexyl methyl methacrylate; α-alkyl epoxyalkyl acrylate such as glycidyl α-ethylacrylate, glycidyl α-n-propylacrylate, glycidyl α-n-butylacrylate, or 6,7-epoxyheptyl α-ethylacrylate; vinylbenzyl glycidyl ether such as o-vinylbenzyl glycidyl ether, m-vinylbenzyl glycidyl ether, or p-vinylbenzyl glycidyl ether; or a combination of the compounds.

The unsaturated compound (a-2-2) containing an epoxy group can be used alone or in multiple combinations.

Based on a total usage amount of 100 parts by weight of the unsaturated carboxylic acid or unsaturated carboxylic anhydride compound (a-2-1), the unsaturated compound (a-2-2) containing an epoxy group, and the other unsaturated compounds (a-2-3), the usage amount of the unsaturated compound (a-2-2) containing an epoxy group is 20 parts by weight to 40 parts by weight, preferably 22 parts by weight to 38 parts by weight, and more preferably 25 parts by weight to 35 parts by weight.

Other Unsaturated Compounds (a-2-3)

The copolymer of the alkali-soluble resin (A-2) can also contain other structural units other than the structural unit having a carboxyl group and the structural unit having an epoxy group, wherein the other structural units are from the other unsaturated compounds (a-2-3).

Specific examples of the other unsaturated compounds (a-2-3) include (meth)acryloyloxypropyl trialkoxysilane, alkyl (meth)acrylate, alicyclic alkyl (meth)acrylate, unsaturated hetero five-membered ring or six-membered ring (meth)acrylate containing an oxygen atom, aryl (meth)acrylate, unsaturated dicarboxylic acid diester, a maleimide compound, hydroxyalkyl ester of (meth)acrylic acid, (meth)acrylamide, aromatic vinyl compound, 1,3-butadiene, or a combination of the compounds.

Specific examples of the (meth)acryloyloxypropyl trialkoxysilane include 3-methacryloyloxypropyl trimethoxysilane, 3-acryloyloxypropyl trimethoxysilane, 3-methacryloyloxypropyl triethoxysilane, 3-acryloyloxypropyl triethoxysilane, or a combination of the compounds.

Specific examples of the alkyl (meth)acrylate include methyl methacrylate, ethyl methacrylate, n-butyl methacrylate, sec-butyl methacrylate, tert-butyl methacrylate, methyl acrylate, ethyl acrylate, n-butyl acrylate, sec-butyl acrylate, tert-butyl acrylate, or a combination of the compounds.

Specific examples of the alicyclic alkyl (meth)acrylate include cyclopentyl methacrylate, cyclohexyl methacrylate, 2-cyclohexyl methyl methacrylate, tricyclo[5.2.1.0^{2,6}]decane-8-yl-methacrylate (also referred to as dicyclopentanyl(meth)acrylate, and in the following, tricyclo[5.2.1.0²′⁶]decane-8-yl is also referred to as “dicyclopentanyl”), 2-dicyclopentyloxy ethyl methacrylate, isobonyl methacrylate, cyclopentyl acrylate, cyclohexyl acrylate, 2-cyclohexyl methacrylate, tricyclo[5.2.1.0^{2,6}]decane-8-yl-acrylate, 2-dicyclopentyloxy ethyl acrylate, isobomyl acrylate, or a combination of the compounds.

Specific examples of the unsaturated hetero five-membered ring or six-membered ring methacrylate containing an oxygen atom include an unsaturated compound containing a tetrahydrofuran skeleton, an unsaturated compound containing a furan skeleton, an unsaturated compound containing a tetrahydropyran skeleton, an unsaturated compound containing a pyran skeleton, or a combination thereof. Specific examples of the unsaturated compound containing a tetrahydrofuran skeleton include tetrahydrofiirfuryl (meth)acrylate, tetrahydrofurfuryl 2-methacryloyloxy-propionate, 3-(meth)acryloyloxy tetrahydrofuran-2-one, or a combination of the compounds. Specific examples of the unsaturated compound containing a furan skeleton include 2-methyl-5-(3-furyl)-1-pentene-3-one, furfuryl (meth)acrylate, 1-furan-2-butyl-3-en-2-one, 1-furan-2-butyl-3-methoxy-3-en-2-one, 6-(2-furyl)-2-methyl-1-hexene-3-one, 6-furan-2-yl-hex-1-en-3-one, 2-furan-2-yl-1-methylethyl acrylate, 6-(2-furyl)-6-methyl-1-heptene-3-one, or a combination of the compounds. Specific examples of the unsaturated compound containing a tetrahydropyran skeleton include (tetrahydropyran-2-yl)methyl methacrylate, 2,6-dimethyl-8-(tetrahydropyran-2-yloxy)-oct-1-ene-3-one, 2-tetrahydropyran-2-methacrylate, 1-(tetrahydropyran-2-yloxy)-butyl-3-en-2-one, or a combination of the compounds.

Specific examples of the unsaturated compound containing a pyran skeleton include 4-(1,4-dioxa-5-oxo-6-heptenyl)-6-methyl-2-pyran, 4-(1,5-dioxa-6-oxo-7-octenyl)-6-methyl-2-pyran, or a combination of the compounds.

Specific examples of the hydroxyalkyl ester of (meth)acrylic acid include 2-hydroxyethyl (meth)acrylate, 2-hydroxypropyl (meth)acrylate, 3-hydroxypropyl (meth)acrylate, 2,3-dihydroxypropyl (meth)acrylate, or a combination of the compounds.

Specific examples of the aryl (meth)acrylate include phenyl (meth)acrylate, benzyl (meth)acrylate, or a combination of the compounds.

Specific examples of the unsaturated dicarboxylic acid diester include diethyl maleate, diethyl fumarate, diethyl itaconate, or a combination of the compounds.

Specific examples of the maleimide compound include N-phenyl maleimide, N-cyclohexyl maleimide, N-benzyl maleimide, N-(4-hydroxyphenyl)maleimide,

N-(4-hydroxybenzyl)maleimide, N-succinimidyl-3-maleimide benzoate,

N-succinimidyl-4-maleimide butyrate, N-succinimidyl-6-maleimide hexanoate, N-succinimidyl-3-maleimide propionate, N-(9-acridinyl)maleimide, or a combination of the compounds.

Specific examples of the (meth)acrylamide include acrylamide, methacrylamide, 4-hydroxyphenyl acrylamide, 4-hydroxyphenyl methacrylamide, 3-hydroxyphenyl acrylamide, 3-hydroxyphenyl methacrylamide, or a combination of the compounds.

The aromatic vinyl compound includes styrene, α-methylstyrene, or a combination of the compounds.

The other unsaturated compounds (a-2-3) preferably include (meth)acryloyloxypropyl trialkoxysilane, an aromatic vinyl compound, maleimide compound, alicyclic alkyl (meth)acrylate, or (meth)acrylamide, more preferably (meth)acryloyloxypropyl trialkoxysilane.

The other unsaturated compounds (a-2-3) can be used alone or in multiple combinations.

Based on a total usage amount of 100 parts by weight of the unsaturated carboxylic acid or unsaturated carboxylic anhydride compound (a-2-1), the compound (a-2-2) containing an epoxy group, and the other unsaturated compounds (a-2-3), the usage amount of the other unsaturated compounds (a-2-3) is 20 parts by weight to 65 parts by weight, preferably 24 parts by weight to 60 parts by weight, and more preferably 30 parts by weight to 55 parts by weight.

The alkali-soluble resin (A-2) can be made by, for instance, performing polymerization on the unsaturated carboxylic acid or unsaturated carboxylic anhydride compound (a-2-1) and the unsaturated compound (a-2-2) containing an epoxy group in a solvent under the presence of a polymerization initiator. The other unsaturated compounds (a-2-3) can also be added as needed.

Specific examples of the solvent used in the polymerization reaction include, for instance, alcohol, glycol ether, ethylene glycol alkyl ether acetate, diethylene glycol monoalkyl ether, diethylene glycol dialkyl ether, propylene glycol monoalkyl ether, propylene glycol monoalkyl ether acetate, propylene glycol monoalkyl ether propionate, aromatic hydrocarbon, ketone, ether other than the above, or ester other than the above.

The free-radical polymerization initiator can be suitably selected according to the type of the used compound. Specific examples of the free-radical polymerization initiator include, for instance, an azo compound such as 2,2′-azobis-2-methylbutyronitrile (AMBN), 2,2′-azobisisobutyronitrile, 2,2′-azobis-(2,4-dimethyl valeronitrile) (ADVN), 2,2′-azobis-(4-methoxy-2,4-dimethylvaleronitrile), 4,4′-azobis(4-cyanopentanoic acid), dimethyl-2,2′-azobis(2-methyl propionate), or 2,2′-azobis(4-methoxy-2,4-dimethylvaleronitrile). The free-radical polymerization initiator is preferably, for instance, 2,2′-azobisisobutyronitrile or 2,2′-azobis(2,4-dimethyl valeronitrile). The free-radical polymerization initiator can be used alone or in multiple combinations. Based on a total amount of 100 parts by weight of the monomers, the usage amount of the free-radical polymerization initiator is generally 0.1 parts by weight to 50 parts by weight, preferably 0.1 parts by weight to 20 parts by weight.

Moreover, in the polymerization reaction, a molecular weight modifier can be used to modify the molecular weight. Specific examples of the molecular weight modifier include, for instance, halogenated hydrocarbon such as chloroform or carbon tetrabromide; thiol such as n-hexyl mercaptan, n-octyl mercaptan, n-dodecyl mercaptan, tert-dodecanethiol, or thioglycolic acid; xanthate such as dimethyl xanthogen sulfide or diisopropyl xanthogen disulfide; terpinolene or α-methylstyrene dimer. Based on a total amount of 100 parts by weight of the monomers, the usage amount of the molecular weight modifier is generally 0.1 parts by weight to 50 parts by weight, preferably 0.2 parts by weight to 16 parts by weight, and more preferably 0.4 parts by weight to 8 parts by weight.

Moreover, the polymerization temperature is generally 0° C. to 150° C., preferably 50° C. to 120° C. ; the polymerization time is generally 10 minutes to 20 hours, preferably 30 minutes to 6 hours.

The alkali-soluble resin (A-2) can be used alone or in multiple combinations.

Based on 100 parts by weight of the alkali-soluble resin (A), the usage amount of the alkali-soluble resin (A-2) can be 0 to 70 parts by weight, preferably 0 to 50 parts by weight, and more preferably 1 to 50 parts by weight.

When the photosensitive polysiloxane composition contains the alkali-soluble resin (A-2), the operational reliability of development is better.

Compound (B) having an ethylenically Unsaturated Group

The compound (B) having an ethylenically unsaturated group includes a compound (B-1) having an ethylenically unsaturated group. Moreover, the compound (B) having an ethylenically unsaturated group can further include a urethane(meth)acrylate compound (B-2) having at least six (meth)acryloyl groups and other compounds (B-3).

Compound (B-1) having an ethylenically Unsaturated Group

The compound (B-1) having an ethylenically unsaturated group includes at least one of a (meth)acrylate monomer represented by formula (1) and a (meth)acrylate monomer represented by formula (2).

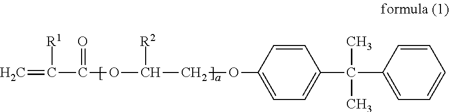

In formula (1), R¹ and R² each independently represent a hydrogen atom or a methyl group; a represents a number of 0 to 4.

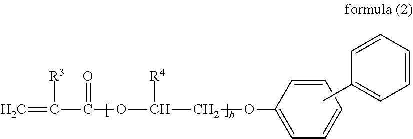

In formula (2), R³ and R⁴ each independently represent a hydrogen atom or a methyl group; b represents a number of 0 to 4.

a and b in formula (1) and formula (2) represent a repeating unit of alkylene oxide, and represent the average number of the repeating unit per molecule.

Specific examples of the (meth)acrylate monomer represented by formula (1) include p-cumyl phenyl (meth)acrylate, p-cumyl phenoxy ethyl (meth)acrylate, or a combination of the compounds.

Specific examples of the (meth)acrylate monomer represented by formula (2) include o-phenylphenyl (meth)acrylate, m-phenylphenyl (meth)acrylate, p-phenylphenyl (meth)acrylate, o-phenylphenoxyethyl (meth)acrylate, m-phenylphenoxyethyl (meth)acrylate, p-phenylphenoxyethyl (meth)acrylate, or a combination of the compounds. Specific examples of the (meth)acrylate monomer represented by formula (2) preferably include o-phenylphenyl (meth)acrylate, o-phenylphenoxyethyl (meth)acrylate, or a combination thereof.

Specific examples of the commercial product include A-LEN-10 made by Shin Nakamura Chemical Co., Ltd.; Aronix TO-1463 or Aronix TO-2344 made by Toagosei Co., Ltd. Specific examples of the commercial product preferably include A-LEN-10 made by Shin Nakamura Chemical Co., Ltd.

Based on 100 parts by weight of the alkali-soluble resin (A), the usage amount of the compound (B-1) having an ethylenically unsaturated group is 0.5 parts by weight to 10 parts by weight, preferably 1 part by weight to 10 parts by weight, more preferably 1 part by weight to 8 parts by weight. When the photosensitive polysiloxane composition does not contain the compound (B-1) having an ethylenically unsaturated group, the issues of poor developing properties and poor operational reliability of development are present.

Urethane(meth)acrylate Compound (B-2) having at Least Six (meth)acryloyl Groups

The urethane(meth)acrylate compound (B-2) having at least six (meth)acryloyl groups can be obtained via a known method. A specific preparation method can include, but is not limited to, for instance: first reacting polyisocyanate with polyol, and then reacting the mixture with (meth)acrylate containing a hydroxyl group to obtain a urethane(meth)acrylate compound; or first reacting polyisocyanate with (meth)acrylate containing a hydroxyl group, and then reacting the mixture with polyol to obtain the urethane(meth)acrylate compound. The urethane(meth)acrylate compound is preferably obtained by first reacting bifunctional polyisocyanate with bifunctional polyol, and then reacting the mixture with pentaerythritol tri(meth)acrylate. More preferably, the preparation method further includes the use of a reaction catalyst, wherein the reaction catalyst can include, but is not limited to, for instance, a known carbamate catalyst such as dibutyltindilaurate.

Specific examples of the (meth)acrylate containing a hydroxyl group include 2-hydroxyethyl(meth)acrylate, hydroxymethyl(meth)acrylate, 2-hydroxypropyl (meth)acrylate, glycidyl di(meth)methacrylate, triglyceride di(meth)acrylate, pentaerythritol tri(meth)acrylate, dipentaerythritol penta(meth)acrylate, dipentaerythritol tetra(meth)acrylate, dipentaerythritol tri(meth)acrylate, dipentaerythritol di(meth)acrylate, trimethylolpropane di(meth)acrylate, epoxy acrylate, or a combination of the compounds. The (meth)acrylate containing a hydroxyl group is preferably pentaerythritol tri(meth)acrylate.

The (meth)acrylate containing a hydroxyl group can be used alone or in multiple combinations.

The polyisocyanate has two or more isocyanate groups inside a molecule. Specific examples of the polyisocyanate include an aromatic compound such as tolylene diisocyanate, diphenyl methane diisocyanate, polymethylene polyphenyl polyisocyanate, toluidine diisocyanate, or naphthalene diisocyanate; hexamethylene diisocyanate, isophorone diisocyanate, xylylene diisocyanate, hydrogenated xylylene diisocyanate, dicyclohexyl methane diisocyanate, or a combination of the compounds. The polyisocyanate can be used alone or in multiple combinations.

Specific examples of the polyol include poly(propylene oxide)glycol, poly(propylene oxide)triol, copoly(ethylene oxide-propylene oxide)glycol, poly(tetrahydrofuran)glycol, ethoxylated bisphenol A, ethoxylated bisphenol S, spiro glycol, caprolactone-modified diol, carbonate diol, trimethylolpropane, pentaerythritol, or a combination of the compounds. The polyol can be used alone or in multiple combinations.

The range of the molecular weight of the urethane(meth)acrylate compound (B-2) having at least six (meth)acryloyl groups can be 1,000 to 200,000, preferably 1,200 to 100,000, more preferably 1,500 to 50,000.

Specific examples of a commercial product of the urethane(meth)acrylate compound (B-2) having at least six (meth)acryloyl groups include purple light UV-1400B, purple light UV-1700B, purple light UV-6300B, purple light UV-7600B, purple light UV-7605B, purple light UV-7610B, or purple light UV-7620EA made by Nippon Synthetic Chemical Industry Co., Ltd.; Art Resin UV-7630B, Art Resin UV-7640B, Art Resin UN-9000H, Art Resin UN-3320HA, Art Resin UN-3320HC, Art Resin UN-3320HS, or Art Resin UN-901T made by Negami Chemical Industrial Co., Ltd.; NK Oligo U-6HA, NK Oligo U-6LPA, NK Oligo U-15HA, NK Oligo UA-32P, NK Oligo U-324A, or NK Oligo U-6H made by Shin Nakamura Chemical Co., Ltd.; EBECRYL 1290, EBECRYL 1290K, EBECRYL 5129, or EBECRYL 220 made by Daicel Cytec Co., Ltd.; Beam Set 575 made by Arakawa Chemical Industries, Ltd. Specific examples of the commercial product of the urethane(meth)acrylate compound (B-2) having at least six (meth)acryloyl groups preferably include purple light UV-1700B, purple light UV-6300B, or purple light UV-7605B made by Nippon Synthetic Chemical Industry Co., Ltd.; NK Oligo U-6HA made by Shin Nakamura Chemical Co., Ltd.; and Art Resin UN-3320HC or Art Resin UN-3320HS made by Negami Chemical Industrial Co., Ltd.

The commercial product of the urethane(meth)acrylate compound (B-2) having at least six (meth)acryloyl groups can be used alone or in multiple combinations.

Based on 100 parts by weight of the alkali-soluble resin (A), the usage amount of the urethane(meth)acrylate compound (B-2) having at least six (meth)acryloyl groups is 1 part by weight to 30 parts by weight, preferably 1 part by weight to 25 parts by weight, more preferably 2 parts by weight to 25 parts by weight. When the photosensitive polysiloxane composition contains the urethane(meth)acrylate compound (B-2) having at least six (meth)acryloyl groups, the operational reliability of development is better.

### Other Compounds (B-3)

The other compounds (B-3) are compounds having an at least bifunctional ethylenically unsaturated group, and in terms of good polymerizability and increased strength of the obtained protective film, the other compounds (B-3) preferably include an at least trifunctional (meth)acrylate.

Specific examples of the bifunctional (meth)acrylate include polyfunctional (meth)acrylate obtained by reacting a divalent aliphatic polyhydroxy compound such as glycol, propanediol, polyethylene glycol, or polypropylene glycol with (meth)acrylic acid, and specific examples thereof include ethylene glycol diacrylate, propylene glycol diacrylate, propylene glycol dimethacrylate, ethylene glycol dimethacrylate, diethylene glycol diacrylate, diethylene glycol dimethacrylate, tetraethylene glycol diacrylate, tetraethylene glycol dimethacrylate, 1,6-hexanediol diacrylate, 1,6-hexanediol dimethacrylate, 1,9-nonanediol diacrylate, 1,9-nonanediol dimethacrylate, or a combination of the compounds. Specific examples of the commercial product of the polyfunctional (meth)acrylate include, for instance, Aronix M-210, Aronix M-240, or Aronix M-6200 (made by Toagosei Co., Ltd.; KAYARAD HDDA, KAYARAD HX-220, or KAYARAD R-604 (made by Nippon Kayaku Co., Ltd.); Viscoat 260, Viscoat 312, or Viscoat 335HP (made by Osaka Organic Chemical Industry, Ltd.); Light Acrylate 1,9-NDA (made by Kyoeisha Chemical, Co., Ltd.)

Specific examples of the at least trifunctional (meth)acrylate include polyfunctional (meth)acrylate obtained by reacting an at least trivalent aliphatic polyhydroxy compound such as glycerine, trimethylol propane, pentaerythritol, or dipentaerythritol with (meth)acrylic acid, and specific examples thereof include trimethylolpropane triacrylate, trimethylolpropane trimethacrylate, pentaerythritol triacrylate, pentaerythritol trimethacrylate, pentaerythritol tetraacrylate, pentaerythritol tetramethacrylate, dipentaerythritol pentaacrylate, dipentaerythritol pentamethacrylate, dipentaerythritol hexaacrylate, a mixture of dipentaerythritol pentaacrylate and dipentaerythritol hexaacrylate, dipentaerythritol hexamethacrylate, ethylene oxide-modified dipentaerythritol hexaacrylate, or a combination of the compounds. Specific examples of a commercial product of the polyfunctional (meth)acrylate include, for instance, Aronix M-309, Aronix M-315, Aronix M-400, Aronix M-405, Aronix M-450, Aronix M-7100, Aronix M-8030, Aronix M-8060, Aronix TO-1450 (made by Toagosei Co., Ltd.); KAYARAD TMPTA, KAYARAD DPHA, KAYARAD DPCA-20, KAYARAD DPCA-30, KAYARAD DPCA-60, KAYARAD DPCA-120, KAYARAD DPEA-12 (made by Nippon Kayaku Co., Ltd.); Viscoat 295, Viscoat 300, Viscoat 360, Viscoat GPT, Viscoat 3PA, Viscoat 400 (made by Osaka Organic Chemical Industry, Ltd.)

Moreover, in addition to tri(2-acryloyloxyethyl)phosphate, tri(2-methacryloyloxyethyl)phosphate, succinic acid-modified pentaerythritol triacrylate, succinic acid-modified dipentaerythritol pentaacrylate, and tri(acryloyloxyethyl)isocyanurate, a polyfunctional acrylic urethane-based compound . . . etc. obtained by reacting a compound having a straight-chain alkylene group and an alicyclic structure and having two or more isocyanate groups with a compound having one or more hydroxyl groups inside the molecule and having three, four, or five (meth)acryloyloxy groups can also be used. Specific examples of a commercial product containing a polyfunctional acrylic polyurethane-based compound include, for instance, New Frontier R-1150 (made by Ichi Kogyo Seiyaku Co., Ltd.), KAYARAD DPHA-40H (made by Nippon Kayaku Co., Ltd.)

Specific examples of the other compounds (B-3) preferably include, for instance, 1,9-nonanediol dimethacrylate, trimethylolpropane triacrylate, pentaerythritol triacrylate, pentaerythritol tetraacrylate, dipentaerythritol pentaacrylate, dipentaerythritol hexaacrylate, or a mixture of dipentaerythritol hexaacrylate and dipentaerythritol pentaacrylate, ethylene oxide-modified dipentaerythritol hexaacrylate, succinic acid-modified pentaerythritol triacrylate, succinic acid-modified dipentaerythritol pentaacrylate, tri(2-acryloyloxyethyl)isocyanurate, or a commercial product containing a polyfunctional acrylic polyurethane-based compound. In particular, an at least trifunctional (meth)acrylate is preferred, especially trifunctional to hexafunctional (meth)acrylate, and a mixture of dipentaerythritol hexaacrylate and dipentaerythritol pentaacrylate is more preferred.

The components of the other compounds (B-3) can be used alone or in multiple combinations.

Based on 100 parts by weight of the alkali-soluble resin (A), the usage amount of the other compounds (B-3) is 3.5 to 60 parts by weight, preferably 8 to 60 parts by weight, and more preferably 12 to 57 parts by weight.

Based on 100 parts by weight of the alkali-soluble resin (A), the usage amount of the compound (B) having an ethylenically unsaturated group is 5 parts by weight to 100 parts by weight, preferably 10 parts by weight to 95 parts by weight, more preferably 15 parts by weight to 90 parts by weight.

### Photoinitiator (C)

The photoinitiator (C) is a photo free-radical polymerization initiator. The photo free-radical polymerization initiator is an active compound generating a curing reaction of the compound (B) having an ethylenically unsaturated group via exposure of radiation such as visible light, ultraviolet, far ultraviolet, electron beam, or X-ray.

Specific examples of the photo free-radical polymerization initiator include, for instance, an 0-acyl oxime compound, an acetophenone compound, an acyl phosphine oxide compound, or a biimidazole compound.

Specific examples of the 0-oxime compound include ethanone,1-[9-ethyl-6-(2-methyl benzoyl)-9H-carbazol-3-yl]-,1-(0-acetyl oxime) (product name: OXE-02; made by Ciba Specialty Chemicals), 1-[9-ethyl-6-benzoyl-9H-carbazol-3-yl]-octane-l-oxime-O-acetate, 1-[9-ethyl-6-(2-methylbenzoyl)-9H-carbazole-3-yl]-ethane-1-oxime-O-benzoate, 1-[9-n-butyl-6-(2-ethylbenzoyl)-9H-carbazole-3-yl]-ethane-1-oxime-O-benzoate, ethanone,1-[9-ethyl-6-(2-methyl-4-tetrahydrofuranylbenzoyl)-9H-carbazole-3-yl]-,1-(O-acetyl oxime), ethanone,1-[9-ethyl-6-(2-methyl-4-tetrahydropyranylbenzoyl)-9H-carbazole-3-yl]-,1-(O-acetyl oxime), ethanone,1-[9-ethyl-6-(2-methyl-5-tetrahydrofuranylbenzoyl)-9H-carbazole-3-yl]-,1-(O-acetyl oxime), ethanone,1-[9-ethyl-6-{2-methyl-4-(2,2-dimethyl-1,3-dioxolanyl)methoxybenzoyl}-9H-carbazole-3-yl]-,1-(O-acetyl oxime), ethanone,1-[9-ethyl-6-(2-methyl-4-tetrahydrofuranylmethoxybenzoyl)-9H-carbazole-3-yl]-,1-(O-acetyl oxime), 1,2-octanedione,1-(4-(phenylthio)phenyl)-,2-(O-benzoyloxime) (product name: OXE-01; made by Ciba Specialty Chemicals), 1-(4-phenyl-thiophenyl)-butane-1,2-dione 2-oxime-O-benzoate, 1-(4-phenyl-thiophenyl)-octane-1-oxime-O-acetate, 1-(4-phenyl-thiophenyl)-butane-1-oxime-O-acetate, or a combination of the compounds. The O-oxime compound can be used alone or in multiple combinations.

Specific examples of the O-acyl oxime compound preferably include ethanone,1-[9-ethyl-6-(2-methyl benzoyl)-9H-carbazol-3-yl]-,1-(O-acetyl oxime), ethanone,1-[9-ethyl-6-(2-methyl-4-tetrahydrofuranylmethoxybenzoyl)-9H-carbazole-3-yl]-,1-(O-acetyl oxime), ethanone,1[9-ethyl-6-{2-methyl-4-(2,2-dimethyl-1,3-dioxolanyl)methoxybenzoyl}-9H-carbazol-3-yl]-,1-(O-acetyl oxime), 1,2-octanedione,1-(4-(phenylthio)phenyl)-,2-(O-benzoyloxime), or a combination of the compounds.

Specific examples of the acetophenone compound include an α-amino ketone compound or an α-hydroxy ketone compound. The acetophenone compound can be used alone or in multiple combinations.

Specific examples of the α--amino ketone compound include 2-benzyl-2-dimethylamino-1-(4-morpholinophenyl)-butane-1-one, 2-dimethylamino-2-(4-methylbenzyl)-1-(4-morpholino-4-yl-phenyl)-butane-1-one, 2-methyl-1-(4-methylthiophenyl)-2-morpholino-1-propanone (product name: IRGACURE 907; made by Ciba Specialty Chemicals Co., Ltd.), or a combination of the compounds.

Specific examples of the α-hydroxy ketone compound include 1-phenyl-2-hydroxy-2-methyl propane-1-one, 1-(4-isopropylphenyl)-2-hydroxy-2-methyl propane-1-one, 4-(2-hydroxyethoxy)phenyl-(2-hydroxy-2-propyl)ketone, 1-hydroxycyclohexyl phenyl ketone, or a combination of the compounds.

The acetophenone compound preferably includes an α-amino ketone compound, more preferably 2-dimethylamino-2-(4-methylbenzyl)-1-(4-morpholino-4-yl-phenyl)-butane-1-one, 2-methyl-1-(4-methylthiophenyl)-2-morpholinopropan-1-one, or a combination of the compounds.

Specific examples of the acyl phosphine oxide compound include 2,4,6-trimethyl benzoyl-diphenyl-phosphine oxide, bis(2,4,6-trimethyl benzoyl)-phenyl phosphine oxide, or a combination of the compounds. The acyl phosphine oxide compound can be used alone or in multiple combinations.

The acyl phosphine oxide compound preferably includes bis(2,4,6-trimethyl benzoyl)-phenyl phosphine oxide.

Specific examples of the biimidazole compound include 2,2′-bis(2-chlorophenyl)-4,4′,5,5′-tetrakis(4-ethoxycarbonyl phenyl)-1,2’-biimidazole, 2,2′-bis(2-chlorophenyl)-4,4′,5,5′-tetraphenyl-1,2′-biimidazole, 2,2′-bis(2,4-dichlorophenyl)-4,4′,5,5′-tetraphenyl-1,2′-biimidazole, 2,2′-bis(2,4,6-trichlorophenyl)-4,4′,5,5′-tetraphenyl-1,2′-biimidazole, or a combination of the compounds. The biimidazole compound can be used alone or in multiple combinations.

The biimidazole compound preferably includes 2,2′-bis(2-chlorophenyl)-4,4′,5,5′-tetraphenyl-1,2′-biimidazole, 2,2′-bis(2,4-dichlorophenyl)-4,4′,5,5′-tetraphenyl-1,2′-biimidazole, 2,2′-bis(2,4,6-trichlorophenyl)-4,4′,5,5′-tetraphenyl-1,2′-biimidazole, or a combination of the compounds.

Moreover, when a biimidazole compound is used, at least one selected from an amine-based sensitizer and a hydrogen donor compound can be added.

Specific examples of the amine-based sensitizer include N-methyl diethanolamine, 4,4′-bis(dimethylamino)benzophenone, 4,4′-bis(diethylamino)benzophenone, ethyl p-dimethylaminobenzoate, isoamyl p-dimethylaminobenzoate, or a combination of the compounds. The amine-based sensitizer preferably includes 4,4′-bis(diethylamino)benzophenone.

Specific examples of the hydrogen donor compound include a thiol-based compound. The thiol-based compound preferably includes 2-mercaptobenzothiazole, 2-mercaptobenzooxazole, 2-mercaptobenzoimidazole, or a combination of the compounds.

The photoinitiator (C) can be used alone or in multiple combinations. In the invention, the photoinitiator (C) preferably contains an O-acyl oxime compound or an α-amino ketone compound.

Based on 100 parts by weight of the alkali-soluble resin (A), the usage amount of the photoinitiator (C) is 3 to 30 parts by weight, preferably 5 to 30 parts by weight, and more preferably 5 to 25 parts by weight.

### Solvent (D)

The photosensitive polysiloxane composition is generally prepared in a liquid composition form by mixing the solvent (D). The solvent (D) is not particularly limited as long as the solvent (D) can disperse or dissolve each component forming the photosensitive polysiloxane composition, does not react with the components, and has suitable volatility.

The solvent (D) is, for instance, (poly)alkylene glycol monoalkyl ether, (poly)alkylene glycol monoalkyl ether acetate, other ethers, ketone, an alkyl lactate, other esters, an aromatic hydrocarbon compound, a carboxylic acid amide, or a combination of the solvents.

Specific examples of the (poly)alkylene glycol monoalkyl ether include ethylene glycol monomethyl ether, ethylene glycol monoethyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, or a combination of the solvents.

Specific examples of the (poly)alkylene glycol monoalkyl ether acetate include ethylene glycol monomethyl ether acetate, ethylene glycol monoethyl ether acetate, propylene glycol monomethyl ether acetate, propylene glycol monoethyl ether acetate, or a combination of the solvents.

Specific examples of the other ethers include diethylene glycol dimethyl ether, diethylene glycol methyl ethyl ether, diethylene glycol diethyl ether, tetrahydrofuran, or a combination of the solvents.

Specific examples of the ketone include methyl ethyl ketone, cyclohexanone, 2-heptanone, 3-heptanone, or a combination of the solvents.

Specific examples of the alkyl lactate include methyl 2-hydroxypropionate, ethyl 2-hydroxypropionate, or a combination of the solvents.

Specific examples of the other esters include methyl 2-hydroxy-2-methylpropionate, ethyl 2-hydroxy-2-methylpropionate, methyl 3-methoxypropionate, ethyl 3-methoxypropionate, methyl 3-ethoxypropionate, ethyl 3-ethoxypropionate (EEP), ethyl ethoxyacetate, ethyl hydroxyacetate, methyl 2-hydroxy-3-methylbutyrate, 3-methyl-3-methoxybutyl acetate, 3-methyl-3-methoxybutylpropionate, ethyl acetate, n-propyl acetate, isopropylacetate, n-butyl acetate, isobutyl acetate, n-pentyl acetate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, or a combination of the solvents.

Specific examples of the aromatic hydrocarbon compound include toluene, xylene, or a combination of the solvents.

Specific examples of the carboxylic acid amide include N-methylpyrrolidone, N,N-dimethyl formamide, N,N-dimethyl acetamide, or a combination of the solvents.

The solvent (D) can be used alone or in multiple combinations.

Based on 100 parts by weight of the alkali-soluble resin (A), the usage amount of the solvent (D) is 50 to 500 parts by weight, preferably 80 to 450 parts by weight, and more preferably 100 to 400 parts by weight.

### Additive (E)

The photosensitive polysiloxane composition of the invention can contain various additives (E) as needed.

Specific examples of the additive include a radiation-sensitive acid-generating agent such as triphenylsulfonium salt or tetrahydrothiophenium salt; a radiation-sensitive base-generating agent such as 2-nitrobenzylcyclohexyl carbamate or 0-carbamoyl hydroxy amide; a surfactant such as a nonionic surfactant, a fluorine-based surfactant, and a silicone-based surfactant; an antioxidant such as 2,2-thiobis(4-methyl-6-tert-butyl phenol) or 2,6-sec-tert-butyl phenol; 2-(3-tert-butyl-5-methyl-2-hydroxy phenyl)-5-chloro benzotriazole; a UV absorber such as alkoxy benzophenone; and an adhesion promoter.

Specific examples of the surfactant include a KP product made by Shin-Etsu Chemical Co., Ltd., an SF-8427 product made by Dow Corning Toray Co., Ltd., a Polyflow product made by Kyoeisha Chemical Co., Ltd., an F-Top product made by Tochem Products Co., Ltd., a Megafac product made by DIC Corporation, a Fluorade product made by Sumitomo 3M Limited, an Asahi Guard product made by Asahi Glass Co., Ltd., or a Surflon product made by Asahi Glass Co., Ltd.

Specific examples of the adhesion promoter include vinyltrimethoxysilane, vinyltriethoxysilane, vinyl-tris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldiethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-(meth)acryloyloxy propyltrimethoxysilane, 3-mercaptopropyltrimethoxysilane, or a combination of the compounds.

The additive (E) can be used alone or in multiple combinations, and the usage amount of the additive (E) can be suitably selected without compromising the object of the invention.

<Preparation Method of Photosensitive polysiloxane Composition>

The photosensitive polysiloxane composition of the invention is a negative-type photosensitive composition. A method that can be used to prepare the photosensitive polysiloxane composition includes, for instance: placing and stirring the alkai-soluble resin (A), the compound (B) having an ethylenically unsaturated group, the photoinitiator (C), and the solvent (D) in a stirrer such that the compositions are uniformly mixed into a solution state. When needed, the additive (E) can also be added. After the compositions are uniformly mixed, a photosensitive polysiloxane composition in a solution state can be obtained.

### <Protective Film and Forming Method Thereof>

The invention further provides a protective film formed by coating the above photosensitive polysiloxane composition on an element, and then performing pre-bake, exposure, development, and post-bake.

The invention further provides an element having a protective film, including an element and the above protective film, wherein the protective film covers the element. Specifically, the element having a protective film is, for instance, a core material or a covering material of a planarizing film, an interlayer insulating film, or an optical waveguide used in a liquid crystal display element and an organic electroluminescent display.

In the following, a substrate is used as the element, and the method in which the photosensitive polysiloxane composition of the invention is used to form a protective film on the substrate is described. The invention contains the following step (1) to step (4).

(1) a step in which the photosensitive polysiloxane composition of the invention is coated on a substrate to foini a coating film;

(2) a step in which radiation is irradiated on at least a portion of the coating film formed in step (1);

(3) a step in which development is performed on the coating film irradiated by radiation in step (2) by using an alkali developing solution; and

(4) a step in which heating is performed on the developed coating film in step (3).

### Step (1)

In step (1), after a solution or a dispersion of the photosensitive polysiloxane composition of the invention is coated on a substrate, the solvent is preferably removed by performing heating (pre-bake) on the coating surface to form a coating film. A usable material of the substrate can include, for instance, glass, quartz, silicon, or resin. The resin can include, for instance, polyethylene terephthalate, polybutylene terephthalate, polyether sulfone, polycarbonate, polyimide, cyclic olefin ring-opening polymer, and hydride thereof.

The coating method of the solution or the dispersion of the photosensitive polysiloxane composition is not particularly limited, and a suitable method such as a spraying method, a roll coating method, a spin coat method, a slit die coating method, or a bar coating method can be used. The coating method preferably includes a spin coating method or a slit die coating method. The conditions of pre-bake are also different according to, for instance, the type and the mixing ratio of each component, and preferably can be set to about 70° C. to 120° C. and 1 minute to 10 minutes.

### Step (2)

In step (2), exposure is performed on at least a portion of the coating film formed in step (1). In general, when exposure is performed on a portion of the coating film, exposure is performed via a photomask having a predetermined pattern. The radiation used in the exposure can include, for instance, visible light, ultraviolet, far ultraviolet, electron beam, or X-ray. The radiation preferably has a wavelength within the range of 190 nm to 450 nm, and more preferably contains ultraviolet of 365 nm.

The amount of exposure of the step is set to a value obtained by measuring under a radiation intensity having a wavelength of 365 nm via an illuminometer (OAI model 356 made by OAI Optical Associates Inc.), and is preferably 10 mJ/cm² to 1,000 mJ/cm², more preferably 20 mJ/cm² to 700 mJ/cm².

### Step (3)

In step (3), development is performed on the exposed coating film by using an alkali developing solution to remove the unexposed portion and form a predetermined pattern. As a result, in the photosensitive polysiloxane composition of the invention, the non-irradiation portion of the radiation is removed, and therefore the photosensitive polysiloxane composition of the invention is a negative-type photosensitive composition.

Specific examples of the alkali developing solution include an inorganic alkali developing solution such as sodium hydroxide, potassium hydroxide, sodium carbonate, sodium silicate, sodium metasilicate, or ammonia solution, or an organic alkali developing solution such as tetramethylammonium hydroxide (TMAH) or tetraethyl ammonium hydroxide. In particular, in terms of costs and productivity, an inorganic alkali developing solution is preferred, and a developing solution of alkali metal hydroxide such as sodium hydroxide or potassium hydroxide is more preferred. When an inorganic alkali developing solution is used in the photosensitive polysiloxane composition of the invention, a pattern can also be formed via high resolution and high fineness.

Moreover, in such alkali developing solution, a suitable amount of a water-soluble organic solvent such as methanol or ethanol or a surfactant can also be added. The developing method can include, for instance, a suitable method such as a puddle method, a dipping method, a rocking immersion method, or a shower method. The developing time is different according to the composition of the photosensitive polysiloxane composition, and is preferably around 10 seconds to 180 seconds. After such developing treatment, air drying is performed via, for instance, compressed air or compressed nitrogen after cleaning via running water is performed for, for instance, 30 seconds to 90 seconds, thus forming the desired pattern.

### Step (4)

In step (4), heating (i.e., post-bake) is performed on the coating film patterned via development by using a heating apparatus such as a hot plate or an oven to obtain a protective film having the desired pattern. The heating temperature is, for instance, 120° C. to 250° C. . The heating time is different according to the type of the heating machine. For instance, when the heating step is performed on a hot plate, the heating time can be set to 5 minutes to 30 minutes, and when the heating step is performed in an oven, the heating time can be set to 30 minutes to 90 minutes. A stepwise baking method in which the heating step is performed two times or more can also be used.

The film thickness of the such formed protective film is preferably 0.1 μm to 10 μm, more preferably 0.1 μm to 6 μm, and still more preferably 0.1 μm to 4 μm.

Via the above steps, a protective film having the desired pattern can be formed. Moreover, development can be performed by using an inorganic alkali developing solution, and the developing properties and the operational reliability of development thereof are good. Moreover, since the obtained protective film has such characteristics, the protective film can be suitably used as the protective film of a touch panel of a display element or an interlayer insulating film of a display element.

The following examples are used to further describe the invention. However, it should be understood that, the examples are only exemplary, and are not intended to limit the implementation of the invention.

### SYNTHESIS EXAMPLES AND COMPARATIVE SYNTHESIS EXAMPLES OF POLYSILOXANE (A-1)

Synthesis example A-1-1 to synthesis example A-1-6 of the polysiloxane (A-1) are described below:

### Synthesis Example A-1-1

In a three-necked flask having a volume of 500 ml, 0.05 moles of 3-(triethoxysilyl)propyl succinic anhydride (hereinafter GF-20), 0.3 moles of methyltrimethoxysilane (hereinafter MTMS), 0.65 moles of phenyltrimethoxysilane (hereinafter PTMS), and 200 g of propylene glycol monoethyl ether (hereinafter PGEE) were added, and the mixture was stirred under room temperature while an aqueous solution of oxalic acid (0.40 g of oxalic acid dissolved in 75 g of water) was added within 30 minutes. Then, the three-necked flask was immersed in an oil bath at 30° C. and stirred for 30 minutes. Next, the temperature of the oil bath was raised to 120° C. within 30 minutes. When the temperature of the solution was reduced to 105° C. (i.e., reaction temperature), the solution was continuously heated and stirred to perform polymerization for 6 hours (i.e., polycondensation time). Then, the solvent and the by-products were removed by a distillation method to obtain polysiloxane A-1-1. The type and the usage amount of the components of the polysiloxane A-1-1 are as shown in Table 1.

### Synthesis Example A-1-2 to Synthesis Example A-1-8

The polysiloxane (A-1) (i.e., polysiloxane A-1-2 to polysiloxane A-1-8) of synthesis example A-1-2 to synthesis example A-1-8 was prepared via the same steps as synthesis example A-1-1, and the difference thereof is: the silane monomer component, the solvent, and the catalyst of the polysiloxane (A-1) were changed, and the usage amount, the reaction temperature, and the polycondensation time thereof were changed (as shown in Table 1).

The compounds corresponding to the abbreviations in Table 1 are as shown below.

### Abbreviation Compound

GF-20 3-(triethoxysilyl)propyl succinic anhydride
TMSG 3-(trimethoxysilyl)propyl glutaric anhydride
TMSOX-D 2-oxetanylbutoxypropyltrimethoxysilane
ECETES 2-(3,4-epoxycyclohexyl)ethyltrimethoxysilane
MTMS Methyltrimethoxysilane
DMDMS Dimethyldimethoxysilane
PTMS Phenyltrimethoxysilane
PTES Phenyltriethoxysilane
DMS-S27 Silanol-terminated polysiloxane, made by Gelest Inc.
DMS-S21 Silanol-terminated polysiloxane, made by Gelest Inc.
Silica particle (particle size: 12 nm, dispersant: methanol, made by Catalysts & OSCAR 1132
Chemicals Industries Co., Ltd.)
Silica particle (particle size: 12 nm, dispersant: isopropanol, made by Nissan IPA-ST Chemical Industries)
PGEE Propylene glycol monoethyl ether
DAA Diacetone alcohol (i.e., 4-hydroxy-4-methyl-2-pentanone)
Water DI water
Oxalic acid Oxalic acid

TABLE 1

| | | Synthesis example | | | | | | | |
|---|---|---|---|---|---|---|---|---|---|
| | | A-1-1 | A-1-2 | A-1-3 | A-1-4 | A-1-5 | A-1-6 | A-1-7 | A-1-8 |
| Silane | GF-20 | 0.05 | 0.03 | — | — | — | 0.05 | — | — |
| monomer | TMSG | — | — | 0.05 | — | — | — | 0.05 | — |
| (a-1) | TMSOX-D | — | 0.02 | — | — | 0.02 | — | — | — |
| | ECETES | — | — | — | 0.09 | 0.08 | — | — | — |
| Silane | MTMS | 0.30 | — | — | 0.65 | 0.60 | 0.30 | — | 0.65 |
| monomer | DMDMS | — | 0.40 | 0.60 | — | — | — | 0.60 | — |
| (a-2) | PTMS | 0.65 | 0.40 | 0.33 | — | 0.30 | 0.64 | 0.33 | 0.35 |
| | PTES | — | 0.15 | — | 0.25 | — | — | — | — |
| Siloxane | DMS-S27 | — | — | — | 0.01 | — | — | — | — |
| prepolymer | DMS-S21 | — | — | 0.02 | — | — | — | — | — |
| (a-3) | | | | | | | | | |
| Silica | OSCAR | — | — | — | — | — | 0.01 | — | — |
| particle | 1132 | | | | | | | | |
| (a-4) | IPA-ST | — | — | — | — | — | — | 0.02 | — |
| Solvent (g) | PGEE | 200 | 100 | 200 | 200 | 200 | 200 | 200 | 200 |
| | DAA | — | 100 | — | — | — | — | — | — |
| Catalyst (g) | Water | 75 | 75 | 75 | 75 | 75 | 75 | 75 | 75 |
| | Oxalic acid | 0.40 | 0.40 | 0.35 | 0.45 | 0.40 | 0.40 | 0.35 | 0.45 |

| | | | | | | | | |
|---|---|---|---|---|---|---|---|---|
| Reaction temperature | 105 | 110 | 105 | 110 | 110 | 105 | 105 | 110 |
| (° C.) | | | | | | | | |
| Polycondensation time | 6 | 5 | 6 | 6 | 5 | 6 | 6 | 6 |
| (hours) | | | | | | | | |

### Synthesis Examples and Comparative Synthesis Examples of Alkali-Soluble Resin (A-2)

In the following, synthesis example A-2-1 to synthesis example A-2-5 of the alkali-soluble resin (A-2) are described:

### Synthesis Example A-2-1

3.0 parts by weight of 2,2′-azobis(2,4-dimethyl valeronitrile) (hereinafter ADVN) and 240 parts by weight of diethylene glycol dimethyl ether (hereinafter Diglyme) were added in a flask having a condenser tube and a stirrer. Then, 30 parts by weight of methacrylic acid (hereinafter MAA), 25 parts by weight of 2-(methacryloyloxymethyl)oxetane (hereinafter 2OMMA), 25 parts by weight of dicyclopentanyl methacrylate (hereinafter FA-513M), and 20 parts by weight of a styrene monomer (hereinafter SM) were added, nitrogen substitution was performed, the mixture was slowly stirred, and the temperature of the solution was raised to 70° C. . Then, the temperature was kept at 70° C. for 5 hours to perform polymerization. A solution containing the alkali-soluble resin A-2-1 was thus obtained.

### Synthesis Example A-2-2 to Synthesis Example A-2-5

The alkali-soluble resin (A-2) of synthesis example A-2-2 to synthesis example A-2-5 (i.e., alkali-soluble resin A-2-2 to alkali-soluble resin A-2-5) was prepared with the same steps as synthesis example A-2-1, and the difference thereof is: the monomer, the solvent, and the catalyst of the alkali-soluble resin (A-2) were changed and the usage amount, the reaction temperature, and the polycondensation time thereof were changed (as shown in Table 2).

The compounds corresponding to the abbreviations in Table 2 are as shown below.

### Abbreviation Compound

MAA Methacrylic acid
AA Acrylic acid
HOMS 2-acryloyloxy ethyl succinic acid
EOMMA 3-(methacryloyloxymethyl)-3-ethyloxetane
2OMMA 2-(methacryloyloxymethyl)oxetane
3OMA 3-(acryloyloxymethyl)oxetane
GMA Glycidyl acrylate
EC-MAA 3,4-epoxycyclohexylmethyl methacrylate
HEMA 2-hydroxyethyl methacrylate
FA-513M Dicyclopentanyl methacrylate
IBOMA Isobornyl methacrylate
BzMA Benzyl methacrylate
SM Styrene monomer
Diglyme Diethylene glycol dimethyl ether
PGMEA Propyleneglycol monoethylether acetate
AMBN 2,2′-azobis-2-methylbutyronitrile
ADVN 2,2′-azobis(2,4-dimethyl valeronitrile)

TABLE 2

| | | | Synthesis example | | | | |
|---|---|---|---|---|---|---|---|
| | unit: parts by weight | | A-2-1 | A-2-2 | A-2-3 | A-2-4 | A-2-5 |
| Unsaturated carboxylic acid or | | MAA | 30 | — | — | — | 30 |
| unsaturated carboxylic anhydride | | AA | — | — | 20 | — | — |
| compound (a-2-1) | | HOMS | — | 40 | — | 15 | — |
| Unsaturated | Unsaturated compound | EOMMA | — | — | 40 | — | — |
| compound | (a-2-2a) containing an | 2OMMA | 25 | — | — | — | — |
| (a-2-2) | oxetanyl group | 3OMA | — | — | — | 20 | — |
| containing | Other unsaturated | GMA | — | — | — | 10 | 20 |
| epoxy group | compounds (a-2-2b) | EC-MAA | — | 20 | — | — | 5 |
| | containing an epoxy group | | | | | | |

| | | | | | | |
|---|---|---|---|---|---|---|
| Other unsaturated compounds (a-2-3) | HEMA | — | 5 | — | — | 10 |
| | FA-513M | 25 | 15 | — | 25 | 10 |
| | IBOMA | — | — | 20 | — | — |
| | BzMA | — | — | 20 | — | 25 |
| | SM | 20 | 20 | — | 30 | — |
| Solvent | Diglyme | 240 | — | 240 | 220 | 200 |
| | PGMEA | — | 240 | — | — | 40 |
| Catalyst | AMBN | — | — | — | — | 3.0 |
| | ADVN | 3.0 | 2.4 | 2.6 | 3.0 | — |
| Reaction temperature (° C.) | | 70 | 70 | 70 | 70 | 70 |
| Polycondensation time (hours) | | 5 | 6 | 6 | 6 | 5 |

### Examples and Comparative Examples of Photosensitive polysiloxane Composition and Protective Film

Example 1 to example 11 and comparative example 1 to comparative example 3 of the photosensitive polysiloxane composition and the protective film are described below:

### Example 1

a. Preparation of Photosensitive polysiloxane Composition

100 parts by weight of the polysiloxane A-1-1, 0.5 parts by weight of p-cumyl phenyl acrylate (B-1-1), 3.5 parts by weight of dipentaerythritol hexaacrylate (B-3-1), and 3.0 parts by weight of 1,2-octanedione,1-(4-(phenylthio)phenyl)-,2-(O-benzoyloxime) (product name: OXE-01; made by Ciba Specialty Chemicals Co., Ltd.) (C-2) were added to 50 parts by weight of propylene glycol monomethyl ether acetate (D-1), and after uniformly stirring via a shaking-type stirrer, the photosensitive polysiloxane composition of example 1 was obtained. The photosensitive polysiloxane composition of example 1 was evaluated via the evaluation methods below, and the results thereof are as shown in Table 3.

b. Forming of Protective Film

The photosensitive polysiloxane composition of example 1 was coated on a glass substrate having a size of 100×100×0.7 mm³ via a method of spin coating to form a coating film having a thickness of about 2.2 μm. Next, the coating film was pre-baked under 90° C. for 2.5 minutes to form a pre-baked coating film. Then, a photomask for negative photoresist was disposed between an exposure machine and the pre-baked coating film, and patterning exposure was performed on the pre-baked coating film via 100 mJ/cm² of ultraviolet (model of exposure machine: AG500-4N, made by M&R Nano Technology). Then, the substrate having the exposed pre-baked coating film thereon was developed via a 0.05% aqueous solution of potassium hydroxide (KOH) under 23° C. for 60 seconds to remove the unexposed portion of the coating film on the glass substrate. Next, the glass substrate was washed with water. Then, post-bake was performed on the developed pre-baked coating film via an oven under 235° C. for 30 minutes to form a protective film on the glass substrate.

### Example 2 to Example 11

The photosensitive polysiloxane compositions and the protective films of example 2 to example 11 were respectively prepared via the same steps as example 1, and the difference thereof is: the type of the components and the usage amount thereof were changed, as shown in Table 3. The obtained protective films of examples 2 to 11 were evaluated via the evaluation methods below, and the results thereof are as shown in Table 3.

### Comparative Example 1 to Comparative Example 3

The photosensitive polysiloxane compositions and the protective films of comparative example 1 to comparative example 3 were respectively prepared via the same steps as example 1, and the difference thereof is: the type of the components and the usage amount thereof were changed, as shown in Table 3. The obtained protective films of comparative example 1 to comparative example 3 were evaluated via the evaluation methods below, and the results thereof are as shown in Table 3.

The compounds corresponding to the abbreviations in Table 3 are as shown below.

### Abbreviation Compound

A-1-1 Polysiloxane A-1-1
A-1-2 Polysiloxane A-1-2
A-1-3 Polysiloxane A-1-3
A-1-4 Polysiloxane A-1-4
A-1-5 Polysiloxane A-1-5
A-1-6 Polysiloxane A-1-6
A-1-7 Polysiloxane A-1-7
A-1-8 Polysiloxane A-1-8
A-2-1 Alkali-soluble resin A-2-1
A-2-2 Alkali-soluble resin A-2-2
A-2-3 Alkali-soluble resin A-2-3
A-2-4 Alkali-soluble resin A-2-4
A-2-5 Alkali-soluble resin A-2-5
B-1-1 p-cumyl phenyl acrylate
B-1-2 m-phenylphenyl acrylate
B-1-3 o-phenylphenoxyethyl acrylate
B-1-4 p-phenylphenoxyethyl acrylate
B-1-5 A-LEN-10 (made by Shin Nakamura Chemical Co., Ltd.)
B-2-1 NK Oligo U-6HA (made by Shin Nakamura Chemical Co., Ltd.) Purple light UV-1700B (made by Nippon Synthetic Chemical Industry Co.,
B-2-2 Purple light UV-17001B (made by Nippon Synthetic Chemical Industry Co., Ltd.)
B-2-3 Purple light UV-7605B (made by Nippon Synthetic Chemical Industry Co., Ltd.)
B-2-4 Art Resin UN-3320HS (made by Negami Chemical Industrial Co., Ltd.)
B-3-1 Dipentaerythritol hexaacrylate
B-3-2 Dipentaerythritol tetraacrylate C-1 Ethanone,1-[9-ethyl-6-(2-methylbenzoyl)-9H-carbazol-3-yl]-,1-(O-acetyloxime) (product name: OXE-02; made by Ciba Specialty Chemicals Co., Ltd.) C-2 1,2-octanedione,1-(4-(phenylthio)phenyl)-,2-(O-benzoyloxime) (roduct name: OXE-01; made by Ciba Specialty Chemicals Co., Ltd) C-3 2-methyl-1-(4-(methylthiophenyl)-2-morpholino-1-propanone (roduct name: IRGACURE 907; made by Ciba Specialty Chemicals Co., Ltd.)
D-1 Propylene glycol monomethyl ether acetate (PGMEA)
D-2 Diacetone alcohol (DAA) (i.e., 4-hydroxy-4-methyl-2-pentanone)
D-3 Ethyl 3-ethoxypropionate (EEP)
E-1 SF-8427 (made by Dow Corning Toray Co., Ltd., surfactant)
E-2 3-glycidoxypropyltrimethoxysilane (product name: KBM403, made by Shin-Etsu Chemical, adhesion promoter)

### [Evaluation Methods]

a. Developing Properties

The photosensitive polysiloxane composition was coated on a glass substrate via a method of spin coating to form a coating film having a thickness of about 2.2 μm. Next, the coating film was pre-baked under 90° C. for 2.5 minutes to form a pre-baked coating film. Then, a photomask (made by Nippon Filcon) of line and space was placed between an exposure machine and the pre-baked coating film, and exposure was performed via 100 mJ/cm² of ultraviolet (model of exposure machine: AG500-4N, made by M&R Nano Technology). Then, the substrate having the exposed pre-baked coating film thereon was developed via a 0.05% aqueous solution of potassium hydroxide (KOH) under 23° C. for 60 seconds to remove the unexposed portion of the coating film on the glass substrate. Moreover, the minimum developable linewidth of the development pattern on the glass substrate was recorded. The evaluation criteria of minimum developable linewidth are as shown below, wherein a smaller minimum developable linewidth represents better developing properties.

\textcircled{◯}: minimum developable linewidth ≦10 μm;

◯: 10 μm<minimum developable linewidth ≦15 μm;

Δ: 15 μm<minimum developable linewidth ≦20 μm;

×: minimum developable linewidth>20 μm.

b. Operational Reliability of Development

The photosensitive polysiloxane composition was coated on a glass substrate via a method of spin coating to form a coating film having a thickness of about 2.2 μm. Next, the coating film was pre-baked under 90° C. for 2.5 minutes to form a pre-baked coating film. Then, a photomask (made by Nippon Filcon) of line and space was placed between an exposure machine and the pre-baked coating film, and exposure was performed via 100 mJ/cm² of ultraviolet (model of exposure machine: AG500-4N, made by M&R Nano Technology). Then, the substrate having the exposed pre-baked coating film thereon was developed via a 0.05% aqueous solution of potassium hydroxide (KOH) under 23° C. to remove the unexposed portion of the coating film on the glass substrate. Moreover, the reduced operation time of development of a 10 ,um linewidth under different times was recorded. The evaluation criteria of the operation time of development are as shown below, wherein a longer operation time of development represents better operational reliability of development.

\textcircled{◯}: operation time of development >210 s;

◯: 210 s≧operation time of development >180 s; Δ: 180 s≧operation time of development >150 s;

×: operation time of development <150 s.

TABLE 3

| | | Example | | | | | |
|---|---|---|---|---|---|---|---|
| Component | | 1 | 2 | 3 | 4 | 5 | 6 |
| Alkai-soluble | A-1-1 | 100 | — | — | — | — | — |
| resin (A) (parts | A-1-2 | — | 100 | — | — | — | — |
| by weight) | A-1-3 | — | — | 100 | — | — | — |
| | A-1-4 | — | — | — | 100 | — | — |
| | A-1-5 | — | — | — | — | 100 | — |
| | A-1-6 | — | — | — | — | — | — |
| | A-1-7 | — | — | — | — | — | — |
| | A-1-8 | — | — | — | — | — | 100 |
| | A-2-1 | — | — | — | — | — | — |
| | A-2-2 | — | — | — | — | — | — |
| | A-2-3 | — | — | — | — | — | — |
| | A-2-4 | — | — | — | — | — | — |
| | A-2-5 | — | — | — | — | — | — |
| Compound (B) | B-1-1 | 0.5 | — | — | — | — | 5 |
| having an | B-1-2 | — | 1 | — | — | — | — |
| ethylenically | B-1-3 | — | — | 2 | — | — | — |
| unsaturated | B-1-4 | | | | 3 | | 2 |
| group (parts | B-1-5 | — | — | — | — | 5 | — |
| by weight) | B-2-1 | — | — | — | — | — | — |
| | B-2-2 | — | — | — | — | — | 20 |
| | B-2-3 | — | — | — | — | — | — |
| | B-2-4 | — | — | — | — | — | — |
| | B-3-1 | 3.5 | 25 | — | 50 | 40 | 30 |
| | B-3-2 | — | — | 30 | — | — | — |
| Photoinitiato | C-1 | — | 3 | — | 20 | — | 20 |
| r (C) (parts | C-2 | 3.0 | 5.0 | 10.0 | — | 10.0 | — |
| by weight) | C-3 | — | — | 5 | — | 10 | 5 |
| Solvent (D) | D-1 | 50 | 100 | — | 300 | — | 300 |
| (parts by | D-2 | — | — | 200 | — | 400 | 50 |
| weight) | D-3 | — | — | — | — | — | — |
| Additive (E) | E-1 | — | 0.1 | — | — | — | — |
| (parts by | E-2 | — | — | — | — | — | — |
| weight) | | | | | | | |
| Test item | Developing | ◯ | ◯ | ◯ | ◯ | ◯ | ◯ |
| | properties | | | | | | |
| | Operational | ◯ | ◯ | ◯ | ◯ | ◯ | ⊚ |
| | reliability of | | | | | | |
| | development | | | | | | |

| | | Example | | | | |
|---|---|---|---|---|---|---|
| Component | | 7 | 8 | 9 | 10 | 11 |
| Alkai-soluble | A-1-1 | — | — | — | — | — |
| resin (A) (parts | A-1-2 | — | — | — | — | — |
| by weight) | A-1-3 | — | — | 70 | — | — |
| | A-1-4 | — | — | — | 90 | — |
| | A-1-5 | — | — | — | — | 50 |
| | A-1-6 | 30 | — | — | — | — |
| | A-1-7 | — | 50 | — | — | — |
| | A-1-8 | — | — | — | — | — |
| | A-2-1 | 70 | — | — | — | — |
| | A-2-2 | — | 50 | — | — | — |
| | A-2-3 | — | — | 30 | — | — |
| | A-2-4 | — | — | — | 10 | — |
| | A-2-5 | — | — | — | — | 50 |
| Compound (B) | B-1-1 | — | — | — | — | 1 |
| having an | B-1-2 | — | — | — | 2 | — |
| ethylenically | B-1-3 | 10 | — | — | 3 | — |
| unsaturated group | B-1-4 | — | — | 5 | — | — |
| (parts by weight) | B-1-5 | — | 3 | — | — | — |
| | B-2-1 | — | 1 | — | 5 | — |
| | B-2-2 | 30 | — | 5 | — | 5 |
| | B-2-3 | — | — | — | 10 | — |
| | B-2-4 | — | — | 5 | — | — |
| | B-3-1 | 30 | 20 | 35 | — | 10 |
| | B-3-2 | 30 | — | — | 25 | — |
| Photoinitiator (C) | C-1 | — | 10 | — | — | 10 |
| (parts by weight) | C-2 | 20.0 | 5.0 | 5.0 | 20.0 | — |
| | C-3 | 10 | — | 10 | — | — |
| Solvent (D) (parts | D-1 | 300 | 200 | — | 200 | — |
| by weight) | D-2 | — | — | 200 | — | 100 |
| | D-3 | 200 | — | 50 | — | — |
| Additive (E) | E-1 | — | — | — | — | — |
| (parts by weight) | E-2 | 2 | — | — | — | — |
| Test item | Developing | ⊚ | ◯ | ⊚ | ⊚ | ◯ |
| | properties | | | | | |
| | Operational | ⊚ | ⊚ | ⊚ | ⊚ | ⊚ |
| | reliability of | | | | | |
| | development | | | | | |

| | | Comparative example | | |
|---|---|---|---|---|
| Component | | 1 | 2 | 3 |
| Alkai-soluble | A-1-1 | 100 | — | — |
| resin (A) (parts | A-1-2 | — | — | — |
| by weight) | A-1-3 | — | — | — |
| | A-1-4 | — | — | — |
| | A-1-5 | — | — | — |
| | A-1-6 | — | — | — |
| | A-1-7 | — | — | — |
| | A-1-8 | — | — | — |
| | A-2-1 | — | 100 | — |
| | A-2-2 | — | — | 100 |
| | A-2-3 | — | — | — |
| | A-2-4 | — | — | — |
| | A-2-5 | — | — | — |
| Compound (B) | B-1-1 | — | — | — |
| having an | B-1-2 | | 2 | — |
| ethylenically | B-1-3 | — | — | — |
| unsaturated group | B-1-4 | — | — | — |
| (parts by weight) | B-1-5 | — | — | — |
| | B-2-1 | — | — | — |
| | B-2-2 | — | — | — |
| | B-2-3 | — | — | — |
| | B-2-4 | — | — | — |
| | B-3-1 | 30 | 25 | 35 |
| | B-3-2 | — | — | — |
| Photoinitiator (C) | C-1 | — | 10.0 | — |
| (parts by weight) | C-2 | 10.0 | — | 10.0 |
| | C-3 | — | — | — |
| Solvent (D) (parts | D-1 | 200 | — | 250 |
| by weight) | D-2 | — | 200 | — |
| | D-3 | — | — | — |
| Additive (E) | E-1 | — | — | — |
| (parts by weight) | E-2 | — | — | — |
| Test item | Developing | X | X | X |
| | properties | | | |
| | Operational | X | X | X |
| | reliability of | | | |
| | development | | | |

### <Evaluation Results>

It is known from Table 3 that, in comparison to the photosensitive polysiloxane composition containing the polysiloxane (A-1) (example 1 to example 11), the operational reliability of development of the photosensitive polysiloxane composition without the polysiloxane (A-1) (comparative example 2 and comparative example 3) is poor.

Moreover, in comparison to the photosensitive polysiloxane composition containing the compound (B-1) having an ethylenically unsaturated group (example 1 to example 11), the developing properties and the operational reliability of development of the photosensitive polysiloxane composition without the compound (B-1) having an ethylenically unsaturated group (comparative example 1 and comparative example 3) are poor.

When the photosensitive polysiloxane composition contains the alkali-soluble resin (A-2) (example 7 to example 11), the operational reliability of development is better.

In the alkali-soluble resin (A-2), when the polymerizable unsaturated compound (a-2-2a) containing an oxetanyl group is used as the unsaturated compound (a-2-2) containing an epoxy group (example 7, example 9, and example 10), the developing properties of the photosensitive polysiloxane composition are better.

When the photosensitive polysiloxane composition contains the urethane(meth)acrylate compound (B-2) having at least six (meth)acryloyl groups (example 6 to example 11), the operational reliability of development is better.

Based on the above, the photosensitive polysiloxane composition of the invention is a negative-type photosensitive composition containing polysiloxane and a compound having an ethylenically unsaturated group (such as (meth)acryloyl group), and therefore the developing properties are good and the operational reliability of development is good. As a result, the photosensitive polysiloxane composition of the invention is suitable for the forming of a protective film, such as a core material or a covering material of a planarizing film, an interlayer insulating film, or an optical waveguide used in a liquid crystal display element and an organic electroluminescent display.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photosensitive polysiloxane composition, comprising:
an alkai-soluble resin (A);
a compound (B) having an ethylenically unsaturated group;
a photoinitiator (C); and
a solvent (D);
wherein the alkali-soluble resin (A) comprises a polysiloxane (A-1),
the compound (B) having an ethylenically unsaturated group comprises a compound (B-1) having an ethylenically unsaturated group, wherein the compound (B-1) having an ethylenically unsaturated group comprises at least one of a (meth)acrylate monomer represented by formula (1) and a (meth)acrylate monomer represented by formula (2), 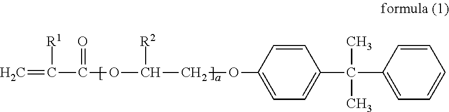
in formula (1), R¹ and R² each independently represent a hydrogen atom or a methyl group; a represents a number of 0 to 4, 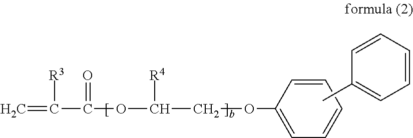
in formula (2), R³ and R⁴ each independently represent a hydrogen atom or a methyl group; b represents a number of 0 to 4.

2. The photosensitive polysiloxane composition of claim 1, wherein the polysiloxane (A-1) is obtained from a polycondensation of a silane monomer component, and the silane monomer component comprises a compound represented by formula (I-1) and a compound represented by formula (I-2),
Si(R^{a})_{w}(OR^{b})_{4-w} formula (I-1)
in formula (I-1), R^{a} each independently represents a hydrogen atom, a C₁ to C₁₀ alkyl group, a C₂ to C₁₀ alkenyl group, a C₆ to C₁₅ aryl group, an alkyl group containing an anhydride group, an alkyl group containing an epoxy group, or an alkoxy group containing an epoxy group, at least one R^{a} is an alkyl group containing an anhydride group, an alkyl group containing an epoxy group, or an alkoxy group containing an epoxy group; R^{b} each independently represents a hydrogen atom, a C₁ to C₆ alkyl group, a C₁ to C₆ acyl group, or a C₆ to C₁₅ aryl group; w represents an integer of 1 to 3,
Si(R^{c})ᵤ(OR^{d})₄₋ᵤ formula (I-2)
in formula (I-2), R^{e} each independently represents a hydrogen atom, a C₁ to C₁₀ alkyl group, a C₂ to C₁₀ alkenyl group, or a C₆ to C₁₅ aryl group; R^{d} each independently represents a hydrogen atom, a C₁ to C₆ alkyl group, a C₁ to C₆ acyl group, or a C₆ to C₁₅ aryl group; and u represents an integer of 0 to 3.

3. The photosensitive polysiloxane composition of claim 1, wherein based on 100 parts by weight of the alkali-soluble resin (A), a usage amount of the polysiloxane (A-1) is 30 parts by weight to 100 parts by weight, a usage amount of the compound (B) having an ethylenically unsaturated group is 5 parts by weight to 100 parts by weight, a usage amount of the compound (B-1) having an ethylenically unsaturated group is 0.5 parts by weight to 10 parts by weight, a usage amount of the photoinitiator (C) is 3 parts by weight to 30 parts by weight, and a usage amount of the solvent (D) is 50 parts by weight to 500 parts by weight.

4. The photosensitive polysiloxane composition of claim 1, wherein the compound (B) having an ethylenically unsaturated group further comprises a urethane(meth)acrylate compound (B-2) having at least six (meth)acryloyl groups.

5. The photosensitive polysiloxane composition of claim 4, wherein based on 100 parts by weight of the alkali-soluble resin (A), a usage amount of the urethane(meth)acrylate compound (B-2) having at least six (meth)acryloyl groups is 1 part by weight to 30 parts by weight.

6. The photosensitive polysiloxane composition of claim 1, wherein the alkali-soluble resin (A) further comprises an alkali-soluble resin (A-2), wherein the alkali-soluble resin (A-2) is obtained by copolymerizing an unsaturated carboxylic acid or unsaturated carboxylic anhydride compound (a-2-1), an unsaturated compound (a-2-2) containing an epoxy group, and other unsaturated compounds (a-2-3).

7. The photosensitive polysiloxane composition of claim 6, wherein the unsaturated compound (a-2-2) containing an epoxy group comprises an unsaturated compound (a-2-2a) containing an oxetanyl group.

8. A protective film formed by coating the photosensitive polysiloxane composition of claim 1 on an element, and then performing pre-bake, exposure, development, and post-bake.

9. An element having a protective film, comprising an element and the protective film of claim 8, wherein the protective film covers the element.
